(19) United States
(12) Patent Application Publication
(10) Pub. No.: US 2025/0104271 A1
(43) Pub. Date: Mar. 27, 2025

(54) ELECTRICAL EQUIPMENT STATE MONITORING SYSTEM, MONITORING SYSTEM, AND ELECTRICAL EQUIPMENT STATE MONITORING METHOD

(71) Applicant: Hitachi, Ltd., Tokyo (JP)

(72) Inventors: Ryotaro KAWAHARA, Tokyo (JP); Akira MURATA, Tokyo (JP); Nobuyuki KUSUNOSE, Tokyo (JP); Takashi KAWAMOTO, Tokyo (JP)

(21) Appl. No.: 18/598,375

(22) Filed: Mar. 7, 2024

(30) Foreign Application Priority Data
Sep. 27, 2023 (JP) 2023-166364

(51) Int. Cl. G06T 7/73; G06T 17/10

(52) U.S. Cl. CPC G06T 7/73; G06T 17/10; G06T 2207/30108

(57) ABSTRACT

Provided are an electrical equipment state monitoring system and the like capable of grasping a three-dimensional aspect of electrical equipment and an electromagnetic field derived from its state.

An electrical equipment state monitoring system for monitoring a state of electrical equipment includes: a reception unit that receives inputs of three-dimensional space information about an area including the electrical equipment and electromagnetic field data including electromagnetic field information regarding an intensity of an electromagnetic field derived from the electrical equipment and three-dimensional coordinates of a point where the electromagnetic field information is acquired; a data superimposing unit that superimposes the three-dimensional space information and the electromagnetic field data in the same space based on the three-dimensional coordinates to generate superimposed data; and a superimposed data output unit that outputs the superimposed data from the electrical equipment state monitoring system.

### BACKGROUND OF THE INVENTION

### 1. Technical Field

The present invention relates to an electrical equipment state monitoring system, a monitoring system, and an electrical equipment state monitoring method. The present invention particularly relates to an electrical equipment state monitoring system and the like that can be suitably used to three-dimensionally grasp a state of electrical equipment.

### 2. Description of the Related Art

Conventionally, there has been a device that estimates a state of electrical equipment by measuring an intensity of an electromagnetic field of the electrical equipment.

In order to remotely measure an electric field source in a patrol area, U.S. Pat. No. 7,248,054 B2 discloses a device including a sensor probe in a moving object to detect an abnormal electric field with respect to a position of the moving object.

WO 2009/028186 A1 discloses a device that detects an electromagnetic field intensity in a space using an electromagnetic field sensor, captures an image of the space including the electromagnetic field sensor, and visualizes a spatial distribution of the electromagnetic field by analyzing the captured image.

A. Pouryazdan, J. C. Costa, R. J. Prance, H. Prance and N. Munzenrieder, Non-contact long range AC voltage measurement, 2019 IEEE SENSORS, 2019, pp. 1-4 discloses a technique for measuring an intensity of an electric field radiated from a power transmission steel tower, a wind turbine, or a utility pole as a distance to a radiation source to estimate a voltage value of the radiation source.

### SUMMARY OF THE INVENTION

However, in the conventional method, for example, a positional relationship of an electromagnetic field is grasped as a two-dimensional image. In this case, since a positional relationship of a measurement target appearing in the two-dimensional image is not grasped, an abnormality of an electric field intensity at each position is also not grasped.

An object of the present invention is to provide an electrical equipment state monitoring system and the like capable of grasping a three-dimensional aspect of electrical equipment and an electromagnetic field derived from its state.

In order to solve the aforementioned problem, the present invention provides an electrical equipment state monitoring system for monitoring a state of electrical equipment, the electrical equipment state monitoring system including: a reception unit that receives inputs of three-dimensional space information about an area including the electrical equipment and electromagnetic field data including electromagnetic field information regarding an intensity of an electromagnetic field derived from the electrical equipment and three-dimensional coordinates of a point where the electromagnetic field information is acquired; a data superimposing unit that superimposes the three-dimensional space information and the electromagnetic field data in the same space based on the three-dimensional coordinates to generate superimposed data; and a superimposed data output unit that outputs the superimposed data from the electrical equipment state monitoring system. In this case, it is possible to provide an electrical equipment state monitoring system capable of grasping a three-dimensional aspect of electrical equipment and an electromagnetic field derived from its state.

Here, the electrical equipment state monitoring system may further include a state determination unit that determines a state of the electrical equipment based on the electromagnetic field data, and the data superimposing unit may further superimpose information on the state of the electrical equipment. In this case, a dangerous area of electromagnetic field exposure in the three-dimensional space can be visualized, making it possible to intuitively and spatially grasp an abnormality of surrounding electrical equipment.

In addition, the state determination unit may determine the state of the electrical equipment based on the electromagnetic field data received by the reception unit and electromagnetic field data acquired in the past. In this case, for example, it is possible to visualize the change by utilizing the fact that a leakage voltage from the electrical equipment or the like appears as an electric field intensity according to an increase in ground resistance value.

Furthermore, the state determination unit may include a baseline calculation unit that calculates a baseline of the electromagnetic field information acquired in the past, and the state determination unit may determine the state based on a discrepancy degree between the electromagnetic field information received by the reception unit and the baseline. In this case, the state can be determined in consideration of the electromagnetic field radiation emitted at the normal time and derived from the normal operation, thereby improving the detection rate.

Furthermore, when the discrepancy degree is larger than a predetermined threshold, the reception unit may output the three-dimensional space information to the data superimposing unit. In this case, the number of calculation targets after the data superimposing unit can be significantly reduced, thereby suppressing the performance of the storage device such as the memory of the calculator or the processor such as the central processing unit (CPU) and reducing the system maintenance cost.

In addition, the state determination unit may calculate a distance between the electrical equipment and the point based on the three-dimensional space information and the three-dimensional coordinates, and determine the state of the electrical equipment further based on information on the distance. In this case, the accuracy in determining the state of the electrical equipment is improved.

In addition, the state determination unit may determine the state of the electrical equipment based on at least one of a voltage, a current, and a power of the electrical equipment obtained by adding the information on the distance. In this case, the state determination unit can determine a state based on the current flowing through the electrical equipment, the voltage applied to the electrical equipment, and the power consumed by the electrical equipment, and a clear index such as a rated voltage, a rated current, or a rated power determined for the electrical equipment can be used as the threshold.

Furthermore, the electromagnetic field data may include vector information that is information on a direction to the electrical equipment, the state determination unit may specify a generation source of the electromagnetic field based on the vector information, and the data superimposing unit may superimpose the three-dimensional space information and the electromagnetic field data based on the specified generation source. In this case, the generation source of the electromagnetic field data can be specified, making it possible to more quickly find an object when an abnormality such as an accident or a failure occurs.

Furthermore, the electrical equipment state monitoring system may further include a difference calculation unit that calculates a difference between a plurality of pieces of three-dimensional space information, and when the difference is larger than a predetermined threshold, the reception unit may output the three-dimensional space information to the data superimposing unit. In this case, the monitoring cost can be reduced by detecting that the electrical equipment or the surroundings thereof have changed by a certain amount or more and performing remote monitoring only in the area.

In addition, the present invention provides a monitoring system including: the electrical equipment state monitoring system according to any one of claims 1 to 9; a three-dimensional space information measurement device that measures the three-dimensional space information; an electromagnetic field measurement device that measures the electromagnetic field information in association with the three-dimensional coordinates of the point; and a display device that displays data superimposed by the electrical equipment state monitoring system, wherein the electromagnetic field measurement device includes: a three-dimensional coordinate measurement device that measures the three-dimensional coordinates; an electromagnetic field sensor that measures at least one of an electric field and a magnetic field as the electromagnetic field information; and a clocking unit that performs time synchronization of data output from the electromagnetic field sensor with the measurement of the three-dimensional coordinates. In this case, even if the measurement timings of the three-dimensional coordinate measurement device and the electromagnetic field sensor are different from each other, data to which the closest times are assigned by the clock can be extracted, and the most appropriate data can be referred to as three-dimensional coordinates at which a measurement is performed by the electromagnetic field sensor.

Here, a measurement timing of the three-dimensional coordinate measurement device and the electromagnetic field sensor may be controlled based on a time measured by the clocking unit. In this case, electromagnetic field information can be periodically updated for a monitoring area and a change in state of the electrical equipment can be periodically monitored.

In addition, the three-dimensional space information measurement device and the electromagnetic field measurement device may be mounted on the same moving object. In this case, since electromagnetic field data and three-dimensional space information can be acquired while moving in the three-dimensional space, monitoring for a wider area and monitoring using information from a plurality of angles can be realized.

Furthermore, the display device may be carried by a worker who measures the electromagnetic field data, and the display device may display an instruction for measurement by an operator who has viewed the superimposed data. In this case, the operator who is located at a remote place can acquire and interpret electrical equipment information at the remote place based on an intuitive instruction.

In addition, the monitoring system according to claim may further include a visualization unit that inputs data superimposed by the electrical equipment state monitoring system and visualizes at least a part of a monitoring target area in a virtual three-dimensional space by the three-dimensional space information and the electromagnetic field data. In this case, a state of electrical equipment existing in a monitoring target area can be intuitively monitored even remotely using electromagnetic field data displayed in the virtual three-dimensional space.

Furthermore, the present invention provides an electrical equipment state monitoring method for monitoring a state of electrical equipment by a processor executing a program recorded in a memory, the method including: receiving inputs of three-dimensional space information about an area including the electrical equipment and electromagnetic field data including electromagnetic field information regarding an intensity of an electromagnetic field derived from the electrical equipment and three-dimensional coordinates of a point where the electromagnetic field information is acquired; superimposing the three-dimensional space information and the electromagnetic field data in the same space based on the three-dimensional coordinates to generate superimposed data; and outputting the superimposed data. In this case, it is possible to provide an electrical equipment state monitoring method capable of grasping a three-dimensional aspect of electrical equipment and an electromagnetic field derived from its state.

According to the present invention, it is possible to provide an electrical equipment state monitoring system and the like capable of grasping a three-dimensional aspect of electrical equipment and an electromagnetic field derived from its state.

### BRIEF DESCRIPTION OF THE DRAWINGS

FIG. 1 is a block diagram illustrating an electrical equipment state monitoring system according to a first embodiment;

FIGS. 2A and 2B are diagrams illustrating examples of electromagnetic field information among electromagnetic field data input to an electromagnetic field data input unit;

FIG. 3 is a diagram illustrating an example of three-dimensional space information, and is a diagram illustrating a case where the three-dimensional space information is three-dimensional point cloud data;

FIG. 4 is a diagram illustrating an example of electromagnetic field data, and is a diagram illustrating an electric field intensity and a magnetic field intensity with respect to a latitude, a longitude, and an altitude;

FIG. 5 is a block diagram illustrating an overall configuration of a monitoring system according to a second embodiment;

FIG. 6 is a flowchart illustrating a method for determining a state of electrical equipment by a state determination unit in the second embodiment;

FIG. 7 is a diagram illustrating electromagnetic field data after a state determination flag is written in the second embodiment;

FIG. 8 is a flowchart illustrating a process when a data superimposing unit further superimposes information on the state of the electrical equipment;

FIG. 9 is a block diagram illustrating an overall configuration of a monitoring system according to a third embodiment;

FIG. 10 is a diagram illustrating electromagnetic field data held by an electromagnetic field data holding unit;

FIG. 11 is a flowchart illustrating a method for determining a state of electrical equipment by a state determination unit in the third embodiment;

FIG. 12 is a diagram illustrating electromagnetic field data after a state determination flag is written in the third embodiment;

FIG. 13 is a block diagram illustrating an overall configuration of a monitoring system according to a fourth embodiment;

FIG. 14 is a flowchart illustrating a method for determining a state of electrical equipment by a state determination unit in the fourth embodiment;

FIG. 15 is a diagram illustrating electromagnetic field data after a state determination flag is written in the fourth embodiment;

FIG. 16 is a diagram illustrating a method for defining a baseline in S1404 of FIG. 14;

FIG. 17 is a block diagram illustrating an overall configuration of a monitoring system according to a fifth embodiment;

FIG. 18 is a block diagram illustrating an overall configuration of a monitoring system according to a sixth embodiment;

FIG. 19 is a diagram illustrating a case where a label indicating electrical equipment exists in three-dimensional point cloud data that is three-dimensional space information;

FIG. 20 is a flowchart illustrating a method for determining a state of electrical equipment further based on information on a distance by a state determination unit in the sixth embodiment;

FIG. 21 is a flowchart illustrating a method for determining a state of electrical equipment further based on information on a distance by a state determination unit in a seventh embodiment;

FIG. 22 is a block diagram illustrating an overall configuration of a monitoring system according to a ninth embodiment;

FIG. 23 is a block diagram illustrating a configuration of an electromagnetic field measurement device according to a tenth embodiment;

FIGS. 24A and 24B are diagrams illustrating examples of data output by an output unit in the tenth embodiment; FIG. 24C is a diagram illustrating formed data;

FIG. 25 is a block diagram illustrating a configuration of an electromagnetic field measurement device according to an eleventh embodiment;

FIG. 26 is a diagram illustrating an example of data output by an output unit in the eleventh embodiment; and

FIG. 27 is a diagram illustrating a method for measuring a state of electrical equipment in a thirteenth embodiment.

### DETAILED DESCRIPTION

Hereinafter, embodiments of the present invention will be described in detail with reference to the accompanying drawings.

Here, the present invention will be described with reference to first to thirteenth embodiments as will described below.

### First Embodiment

Hereinafter, electrical equipment state monitoring using an electrical equipment state monitoring system 100 according to a first embodiment will be described.

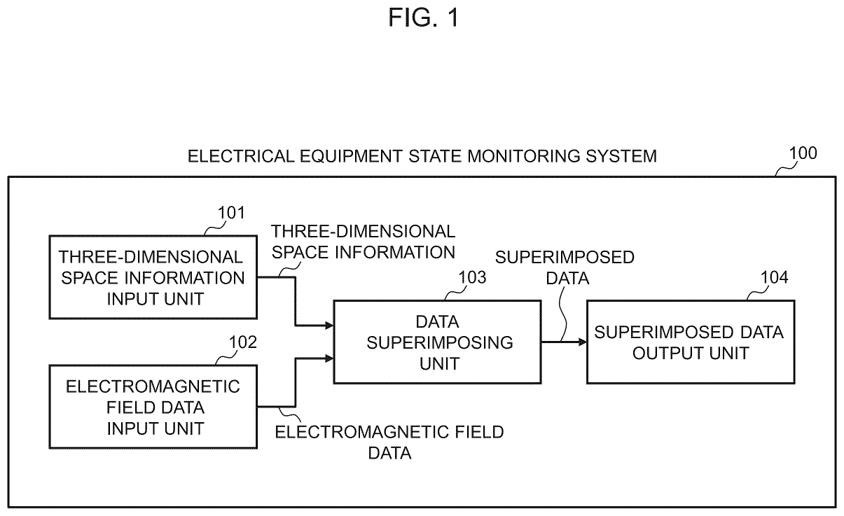

FIG. 1 is a block diagram illustrating the electrical equipment state monitoring system 100 according to the first embodiment. The electrical equipment state monitoring system 100 is a device that monitors a state of electrical equipment. The electrical equipment state monitoring system 100 includes a three-dimensional space information input unit 101, an electromagnetic field data input unit 102, a data superimposing unit 103, and a superimposed data output unit 104.

A user acquires three-dimensional space information about an area including the electrical equipment and electromagnetic field data including electromagnetic field information regarding an intensity of an electromagnetic field derived from the electrical equipment, and three-dimensional coordinates of a point where the electromagnetic field information is acquired, and inputs the three-dimensional space information and the electromagnetic field data to the electrical equipment state monitoring system 100 as illustrated. In the electrical equipment state monitoring system 100, the three-dimensional space information input unit 101 receives an input of three-dimensional space information, and the electromagnetic field data input unit 102 receives an input of electromagnetic field data. In this case, the three-dimensional space information input unit 101 and the electromagnetic field data input unit 102 function as a reception unit that receives inputs of three-dimensional space information and electromagnetic field data. The input three-dimensional space information and electromagnetic field data are output to the data superimposing unit 103 from the three-dimensional space information input unit 101 and the electromagnetic field data input unit 102, respectively. The data superimposing unit 103 generates superimposed data by superimposing the three-dimensional space information and the electromagnetic field data in the same space based on the three-dimensional coordinates. The generated superimposed data is output from the electrical equipment state monitoring system 100 via the superimposed data output unit 104.

The user monitors an electrical equipment state using the superimposed data output from the electrical equipment state monitoring system 100.

The three-dimensional space information input to the system may be acquired by a three-dimensional space information measurement device. The three-dimensional space information measurement device measures three-dimensional space information about the area including the electrical equipment. The three-dimensional space information is data indicating a three-dimensional shape of the electrical equipment or the like. The three-dimensional space information measurement device is, for example, a distance sensor that measures a distance, and is, for example, a laser scanner such as light detection and ranging (LiDAR). The LiDAR measures a three-dimensional shape by scanning a surface of the electrical equipment or the like.

Here, the LiDAR is a device that irradiates an object with a laser and receives reflected light to measure a distance to the object. Based on this principle, the accuracy of distance measurement is relatively high, ranging from several millimeters to several centimeters. Using one straight laser as a basic unit, the LiDAR periodically changes the direction of irradiation one after another at a high speed of several tens of Hz, and thereby, grasps a shape of the surface of the object as a collection of fine points (point cloud). In this case, the three-dimensional space information is data (three-dimensional point cloud data) expressing the three-dimensional shape of the electrical equipment or the like as a point cloud.

The electromagnetic field data input to the system can be acquired by an electromagnetic field measurement device. The electromagnetic field measurement device measures electromagnetic field information including information regarding an intensity of an electromagnetic field of the electrical equipment in association with three-dimensional coordinates of a measurement point where the electromagnetic field information is measured. The electromagnetic field measurement device includes a device that measures electromagnetic field information and three-dimensional coordinates.

As a method of measuring an electric field as the electromagnetic field, a voltage generated across a parallel plate electrode in proportion to a spatial electric field intensity may be converted into digital data by an analog-digital conversion circuit, or a transducer such as an optical electric field element may be used. As a method of measuring a magnetic field as the electromagnetic field, a coil, a magnetoresistive sensor element, or a Hall element may be used.

As a method of measuring three-dimensional coordinates, a satellite positioning system such as a global positioning system (GPS) may be used, or a relative distance from a predetermined reference point may be measured by a sound wave, a beam, or a distance measurement device including various encoders. Here, a horizontal position and a vertical position, that is, a latitude and longitude and an altitude, may be separately measured by different methods.

The three-dimensional space information input unit 101 is a functional unit that receives an input of three-dimensional space information about an area including the electrical equipment.

The three-dimensional space information input to the three-dimensional space information input unit 101 is three-dimensional point cloud data acquired by a laser scanner such as the LiDAR described above, a mobile mapping system (MMS), or the like. However, the three-dimensional space information is not limited thereto, and may be a three-dimensional image acquired by a 3D camera using a time of flight (ToF) method, a stereo method, or the like, a 3D model generated from a plurality of two-dimensional photographs based on photogrammetry or the like, computer aided design (CAD) data obtained by designing and drafting a structure of an object such as electrical equipment on a computer, or the like. The three-dimensional space information is data including some or all of the electrical equipment in a predetermined three-dimensional space. The three-dimensional space information input unit 101 receives an input of three-dimensional space information and outputs the three-dimensional space information to the data superimposing unit 103.

The electromagnetic field data input unit 102 is a functional unit that receives an input of electromagnetic field data including electromagnetic field information regarding an intensity of an electromagnetic field derived from the electrical equipment and three-dimensional coordinates of a point where the electromagnetic field information is acquired, and outputs the electromagnetic field data to the data superimposing unit 103.

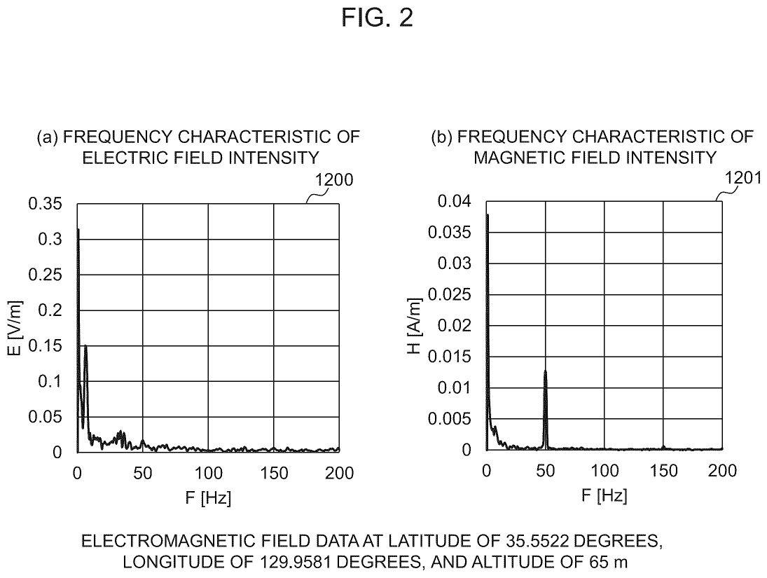

FIGS. 2A and 2B are diagrams illustrating examples of electromagnetic field information among the electromagnetic field data input to the electromagnetic field data input unit 102.

The electromagnetic field refers to an electric field, a magnetic field, or both. Among the electromagnetic field data, FIG. 2A illustrates electric field intensity data 1200, where the horizontal axis represents a frequency and the vertical axis represents an electric field intensity. FIG. 2B illustrates magnetic field intensity data 1201, where the horizontal axis represents a frequency and the vertical axis represents a magnetic field intensity. The electric field intensity data 1200 and the magnetic field intensity data 1201 are examples of electromagnetic field information.

In the electrical equipment to be remotely maintained, a magnetic field or an electric field is generated due to a current flowing in the electrical equipment or a voltage applied to the electrical equipment. It is known that the magnitude of the magnetic field or the electric field varies depending on the current flowing in the electrical equipment or the voltage applied to the electrical equipment. In addition, the current flowing in the electrical equipment or the voltage applied to the electrical equipment is a direct current or an alternating current. When the current flowing in the electrical equipment or the voltage applied to the electrical equipment is an alternating current, currents or voltages having different frequencies may exist at the same time, and the pattern may well indicate a state of the electrical equipment. For example, in East Japan, a power supply frequency derived from a power plant is determined to be 50 Hz. In an electric device that supplies this electric power via a power distribution facility or the like, a magnetic field of 50 Hz is often radiated, and the magnetic field intensity at 50 Hz may be larger than those at other frequencies as shown in the magnetic field intensity data 1201. The electromagnetic field information input to the electromagnetic field data input unit 102 may be data obtained by limiting the frequency through various filters, or may be data obtained by combining intensities measured at a plurality of frequencies into one value using a predetermined function. For example, a total harmonic distortion (THD) calculated based on a power supply frequency and its high-order harmonic component can also be input as the electromagnetic field information. When electromagnetic field information having a frequency band is input, it is preferable to limit the input to a frequency of an order of up to about 50 times the power supply frequency. Usually, in a higher frequency range, the electromagnetic field information includes a large amount of environmental noise that is not derived from the state of the electrical equipment.

In addition, the electromagnetic field data includes three-dimensional coordinates of the position where the electromagnetic field information is acquired. The three-dimensional coordinates may be expressed as a relative distance from coordinates of a reference point, or may be coordinates based on height information such as an altitude in addition to two-dimensional coordinates on the earth indicated by a geodetic system or a projection coordinate system.

The data superimposing unit 103 generates superimposed data by superimposing the three-dimensional space information and the electromagnetic field data in the same space based on the three-dimensional coordinates.

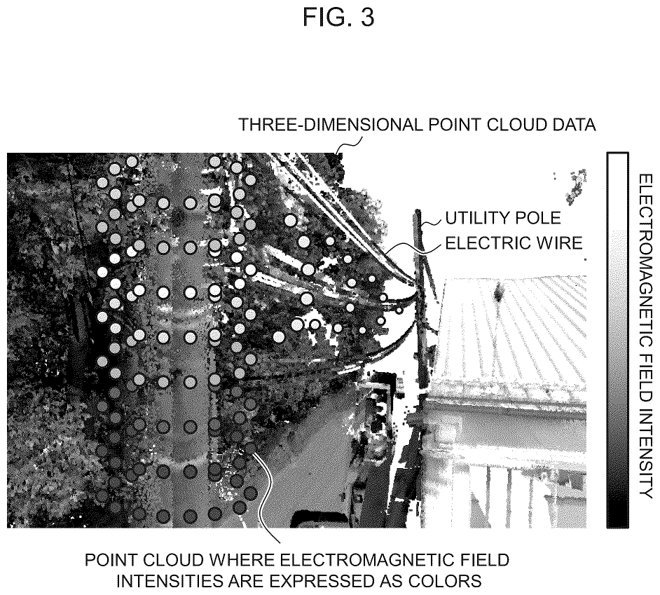

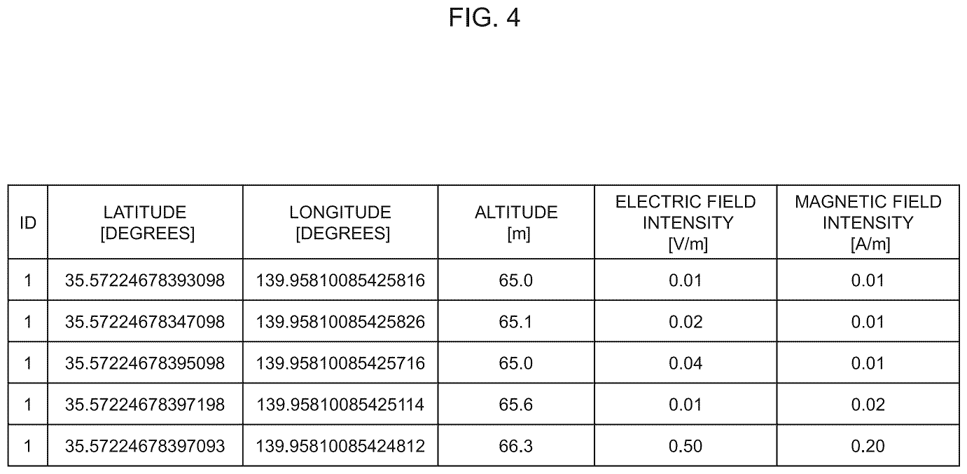

FIG. 3 is a diagram illustrating an example of three-dimensional space information, and is a diagram illustrating a case where the three-dimensional space information is three-dimensional point cloud data. In addition, FIG. 4 is a diagram illustrating an example of electromagnetic field data, and is a diagram illustrating an electric field intensity and a magnetic field intensity with respect to a latitude, a longitude, and an altitude.

The three-dimensional point cloud data is point cloud data including a plurality of three-dimensional coordinates, and can indicate a surface of a tree or the ground, or a surface of electrical equipment such as a utility pole or an electric wire as illustrated in FIG. 3. On the other hand, in the electromagnetic field data, an electromagnetic field intensity with respect to three-dimensional coordinates such as a latitude, a longitude, and an altitude are recorded as illustrated in FIG. 4. For example, the data superimposing unit 103 scales an electric field intensity or a magnetic field intensity of the electromagnetic field information as luminance information such as red or blue for each intensity. In addition, the data superimposing unit 103 generates superimposed data by combining a latitude, a longitude, and an altitude after being converted into a three-dimensional coordinate format of three-dimensional point cloud data. The generated superimposed data is output to the superimposed data output unit 104.

The superimposed data output unit 104 outputs the input superimposed data to the outside of the electrical equipment state monitoring system 100. For example, in a case where the three-dimensional space information is three-dimensional point cloud data, the three-dimensional space information is output in a point cloud file format such as LAS, CSV, or XYZ capable of recording the three-dimensional space information.

The user monitors a state of the electrical equipment by checking the superimposed data output from the electrical equipment state monitoring system 100. For example, a display terminal including a display device is prepared, and superimposed data is visualized by a predetermined program. The display terminal is an example of a display device that displays data superimposed by the electrical equipment state monitoring system 100. The display device may be, for example, a liquid crystal display or a touch panel.

An example of the visualization is illustrated in FIG. 3. FIG. 3 illustrates three-dimensional point cloud data and a point cloud in which electromagnetic field intensities included in electromagnetic field information are expressed as colors in a virtual three-dimensional space. Since the data output from the electrical equipment state monitoring system 100 is three-dimensional data, the data can be expressed as virtual reality (VR) by being displayed as 360-degree content on a head mounted display, or can be expressed as augmented reality (AR) by being displayed in an overlaid state on a two-dimensional image captured by a camera on a display device attached to the camera.

The electrical equipment state monitoring system 100 may be provided as a program. By being run on a server on a cloud, the program may remotely transmit three-dimensional space information and electromagnetic field data to the electrical equipment state monitoring system 100 and remotely connect the electrical equipment state monitoring system 100 to an external display terminal. For example, a measurement device that measures three-dimensional space information and an electromagnetic field measurement device that measures an electromagnetic field may be installed in an area where a monitoring target is installed, and a display terminal may be installed in a control center. In addition, the electrical equipment state monitoring system 100 may be incorporated in the same device as the three-dimensional space information measurement device, the electromagnetic field measurement device, and the display terminal. The use of information such as an electromagnetic field that is invisible to human eyes is advantageous in that surveillance staff is able to conduct advanced monitoring at a site where a monitoring target is present nearby. In addition, three-dimensional space information measurement devices, electromagnetic field measurement devices, and display terminals may exist at a plurality of locations. This is advantageous in that a plurality of locations can be remotely monitored by one hand at the control center.

According to the present embodiment, even at a remote place, it is possible to draw electromagnetic field information caused by the state of the electrical equipment in a virtual three-dimensional space for a monitoring area including the electrical equipment, by inputting three-dimensional space information and electromagnetic field data measured at the site, so that the state of the electrical equipment can be checked. Since the measurement data is displayed in the virtual three-dimensional space so as to be superimposed on the monitoring target, this is advantageous in that the state of the electrical equipment can be monitored at a remote location as if the measurement is performed.

### Second Embodiment

In a second embodiment, a monitoring system 1 including a display terminal 105, a three-dimensional space information measurement device 106, and an electromagnetic field measurement device 107 in addition to the electrical equipment state monitoring system 100 will be described. In addition, the electrical equipment state monitoring system 100 according to the second embodiment determines a state of electrical equipment.

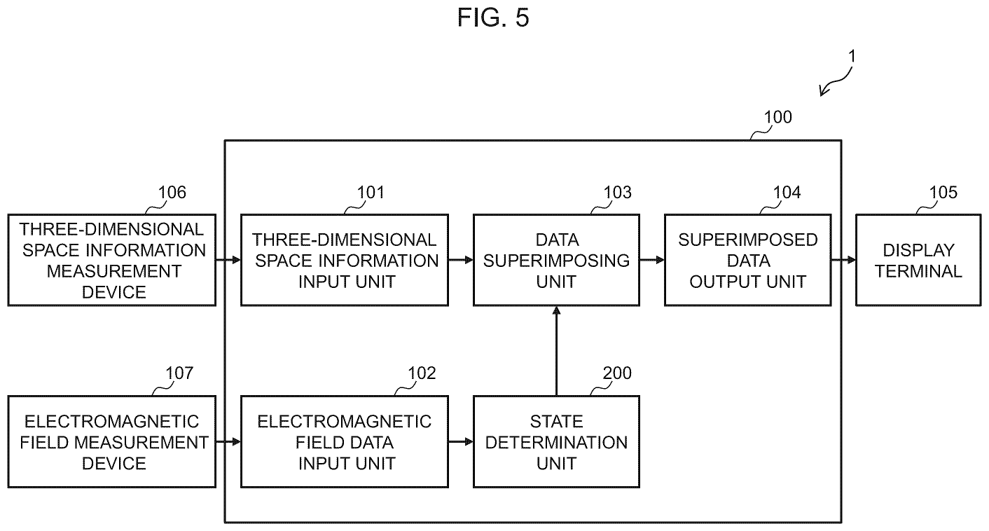

FIG. 5 is a block diagram illustrating an overall configuration of the monitoring system 1 according to the second embodiment.

The electrical equipment state monitoring system 100 of the monitoring system 1 illustrated in FIG. 5 is different from the electrical equipment state monitoring system 100 illustrated in FIG. 1 in that a state determination unit 200 is added, and the other points are the same.

The state determination unit 200 determines the state of the electrical equipment based on electromagnetic field data.

One state determination method in the state determination unit 200 is a determination based on a predefined threshold.

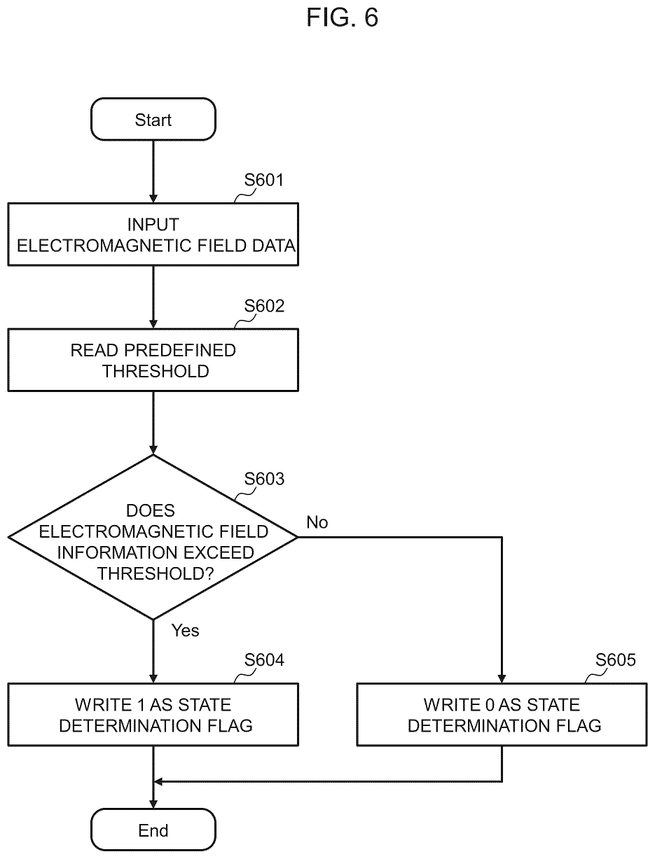

FIG. 6 is a flowchart illustrating a method for determining a state of the electrical equipment by the state determination unit 200 in the second embodiment.

First, the electrical equipment state monitoring system 100 inputs electromagnetic field data to the state determination unit 200 (S601).

Next, the state determination unit 200 reads a predefined threshold (S602).

Then, the state determination unit 200 determines whether electromagnetic field information of the electromagnetic field data exceeds the threshold (S603).

As a result, when the electromagnetic field information of the electromagnetic field data exceeds the threshold (Yes in S603), the state determination unit 200 writes 1 in a state determination flag (S604).

On the other hand, when the electromagnetic field information of the electromagnetic field data is equal to or smaller than the threshold (No in S603), the state determination unit 200 writes 0 in a state determination flag (S605).

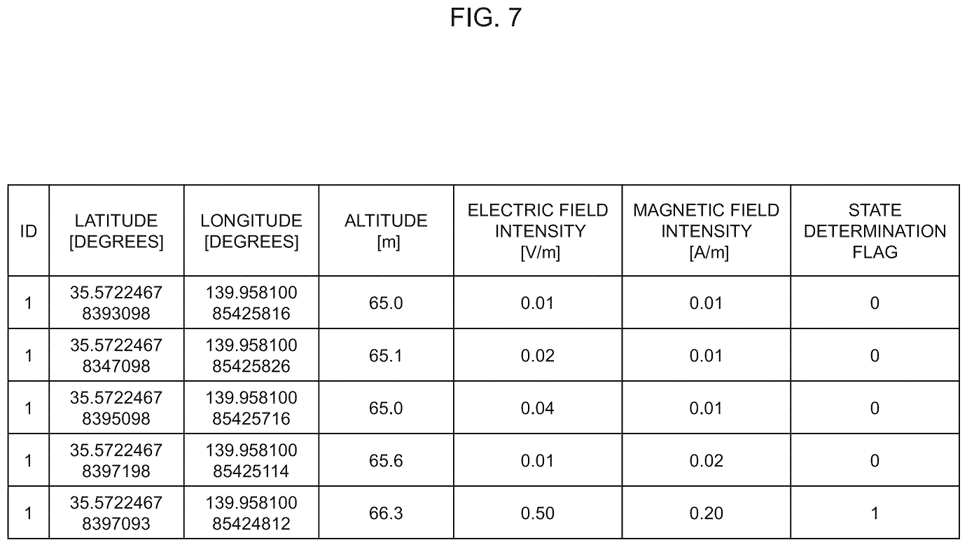

FIG. 7 is a diagram illustrating electromagnetic field data after a state determination flag is written in the second embodiment.

The illustrated electromagnetic field data is obtained by adding a state determination flag to the electromagnetic field data illustrated in FIG. 4. That is, the electromagnetic field data of FIG. 7 is a result obtained by inputting the electromagnetic field data illustrated in FIG. 4 to the state determination unit 200 in S601 and writing 1 or 0 as a state determination flag in S604 or S605.

The data superimposing unit 103 further superimposes information on the state of the electrical equipment.

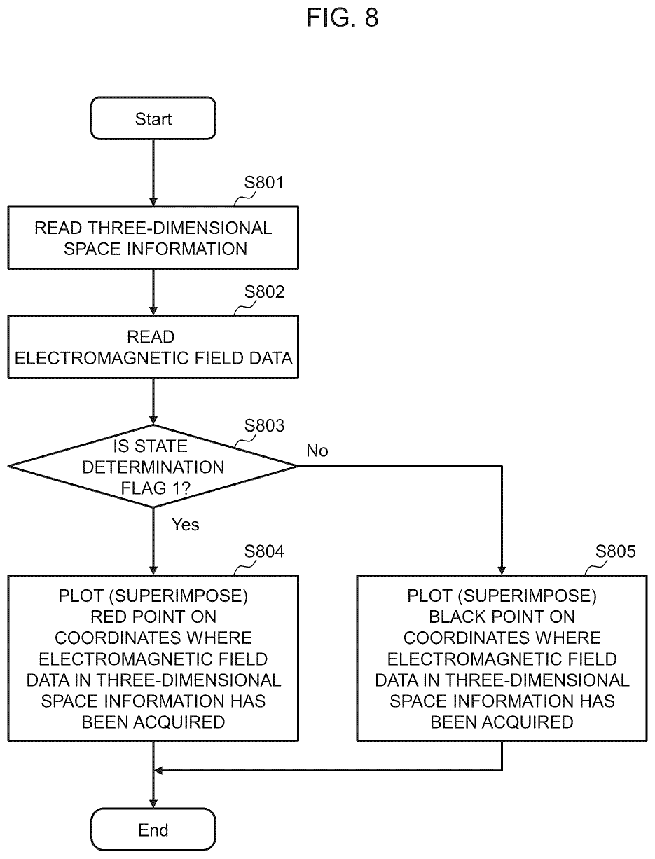

FIG. 8 is a flowchart illustrating a process when the data superimposing unit 103 further superimposes information on the state of the electrical equipment.

First, the data superimposing unit 103 reads three-dimensional space information (S801).

Next, the data superimposing unit 103 reads the electromagnetic field data accompanied by the state determination flag (S802). This is, for example, what is illustrated in FIG. 7.

Then, the data superimposing unit 103 determines whether the state determination flag is 1 (S803).

As a result, when the state determination flag is 1 (Yes in S803), the data superimposing unit 103 plots (superimposes) a red point on the coordinates where the electromagnetic field data in the three-dimensional space information is acquired (S804).

On the other hand, when the state determination flag is 0 (No in S803), the data superimposing unit 103 plots (superimposes) a black point on the coordinates where the electromagnetic field data in the three-dimensional space information is acquired (S805).

In this manner, the data superimposing unit 103 superimposes the data at a position where the electromagnetic field data is acquired in the three-dimensional space, for example, with color information being changed according to the state determination flag.

For example, the International Commission on Non-Ionizing Radiation Protection (ICNIRP) presents a regulation value or a guideline for an intensity of an electromagnetic field radiated from electrical equipment from the viewpoint of safety. As a predefined threshold, for example, this can be used to perform a state determination. The present embodiment is advantageous in that a dangerous area of electromagnetic field exposure in the three-dimensional space can be visualized, making it possible to intuitively and spatially grasp an abnormality of surrounding electrical equipment.

### Third Embodiment

In a third embodiment, the state determination unit 200 determines a state of the electrical equipment based on electromagnetic field data received by the electromagnetic field data input unit 102 and electromagnetic field data acquired in the past.

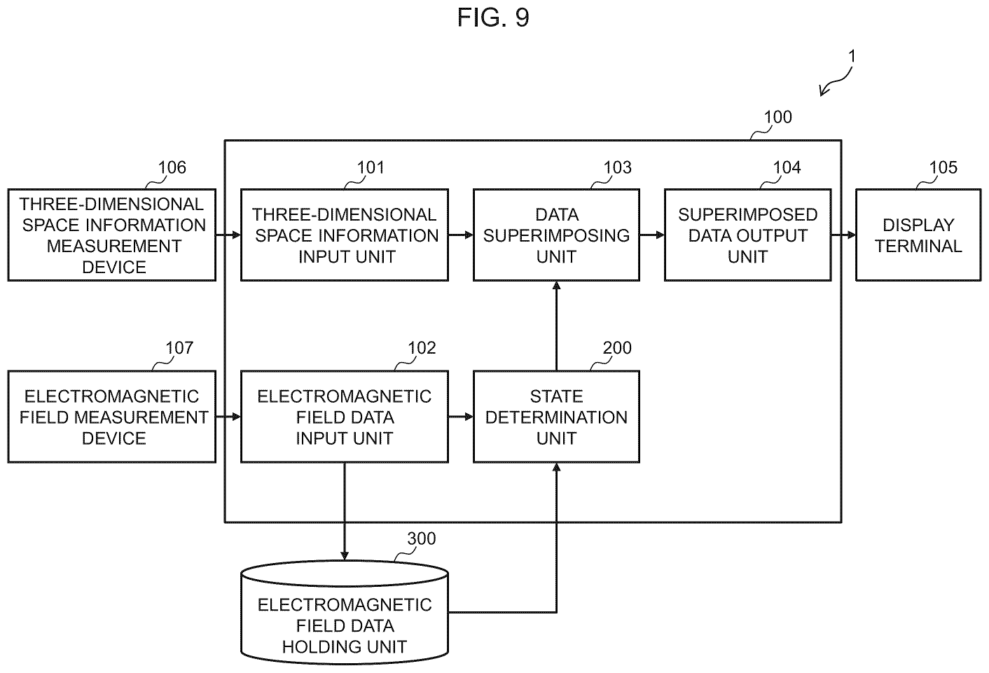

FIG. 9 is a block diagram illustrating an overall configuration of a monitoring system 1 according to the third embodiment.

The monitoring system 1 illustrated in FIG. 9 is different from the monitoring system 1 illustrated in FIG. 5 in that an electromagnetic field data holding unit 300 is added, and the other points are the same.

The electromagnetic field data holding unit 300 is an output destination of the electromagnetic field data input unit 102. Then, the electromagnetic field data input to the state determination unit 200 is output from the electromagnetic field data holding unit 300. Note that the electromagnetic field data holding unit 300 may be provided inside the electrical equipment state monitoring system 100, or may be provided outside the electrical equipment state monitoring system 100 as illustrated in FIG. 9.

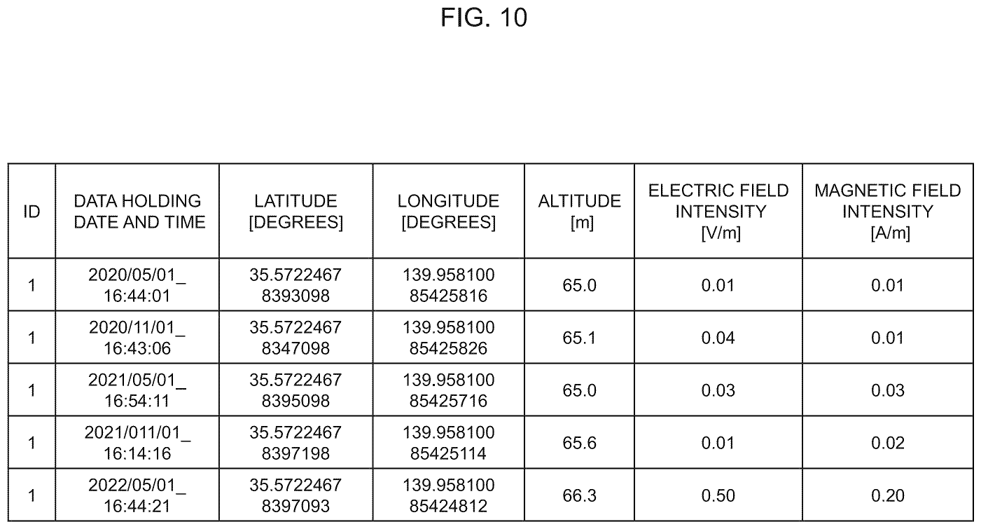

FIG. 10 is a diagram illustrating electromagnetic field data held by the electromagnetic field data holding unit 300.

As illustrated, the electromagnetic field data holding unit 300 holds electromagnetic field data acquired together with a data holding date and time. That is, the illustrated electromagnetic field data is obtained by adding the data holding date and time to the electromagnetic field data illustrated in FIG. 4.

One determination method in the state determination unit 200 according to the present embodiment is a determination of an abnormality based on a difference from past electromagnetic field data.

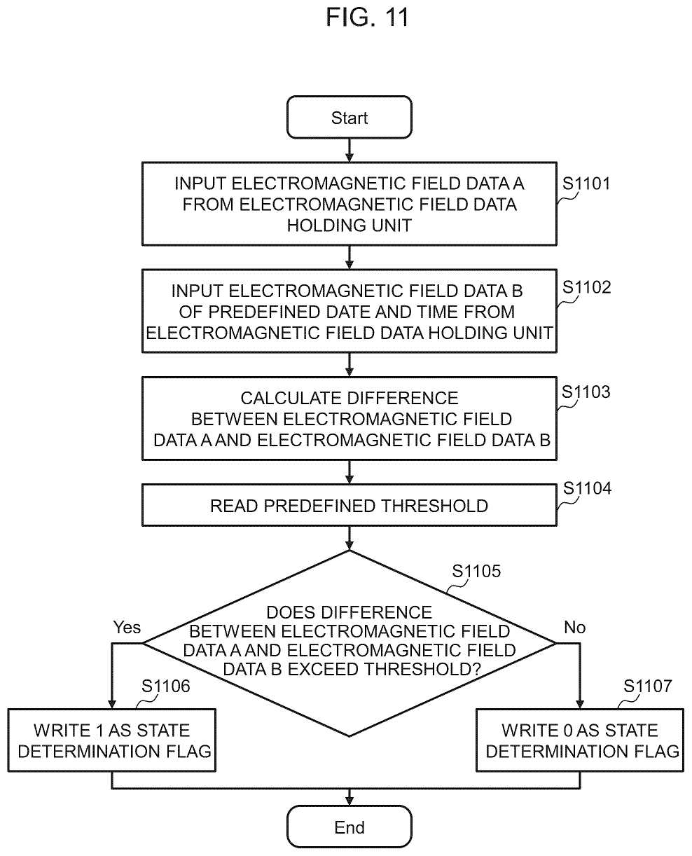

FIG. 11 is a flowchart illustrating a method for determining a state of the electrical equipment by the state determination unit 200 in the third embodiment.

First, the electrical equipment state monitoring system 100 inputs electromagnetic field data A from the electromagnetic field data holding unit 300 to the state determination unit 200 (S1101). The electromagnetic field data A is usually the latest electromagnetic field data.

Next, the electrical equipment state monitoring system 100 inputs electromagnetic field data B of a predefined date and time from the electromagnetic field data holding unit 300 to the state determination unit 200 (S1102). The electromagnetic field data B is, for example, electromagnetic field data measured for the first time for the monitoring target. In addition, the electromagnetic field data B is electromagnetic field data before a certain time such as one year or one hour.

Next, the state determination unit 200 calculates a difference and a change rate between electromagnetic field information included in the electromagnetic field data A and the electromagnetic field data B (S1103).

The state determination unit 200 reads a predefined threshold (S1104).

Then, the state determination unit 200 determines whether or not the calculated difference or change rate exceeds the threshold (S1105).

As a result, when the calculated difference or change rate exceeds the threshold (Yes in S1105), the state determination unit 200 writes 1 as a state determination flag (S1106).

On the other hand, when the calculated difference or change rate is equal to or smaller than the threshold (No in S1105), the state determination unit 200 writes 0 as a state determination flag (S1107).

The calculated difference or change rate can be written in S1106 or S1107.

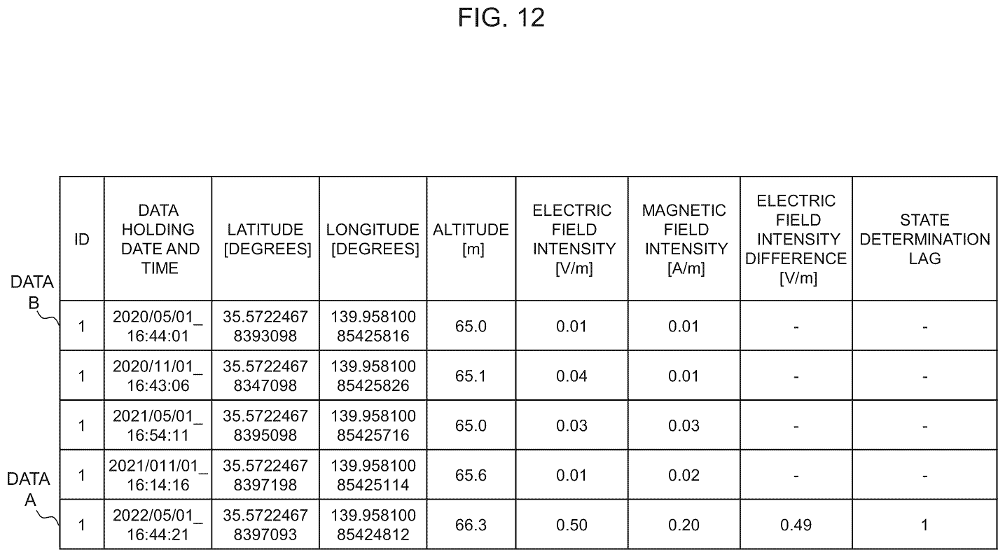

FIG. 12 is a diagram illustrating electromagnetic field data after a state determination flag is written in the third embodiment.

The illustrated electromagnetic field data is obtained by adding a difference in electric field intensity and a state determination flag to the electromagnetic field data illustrated in FIG. 10. That is, in the electromagnetic field data of FIG. 12, the electromagnetic field data illustrated in FIG. 10 is input from the electromagnetic field data holding unit 300 to the state determination unit 200 in S1101 and S1102. The electromagnetic field data of FIG. 12 is a result of writing the difference in electric field intensity and the state determination flag in S1106 or S1107.

For example, electrical equipment may be earthed (grounded) inside, and a ground resistance is measured as a state of the electrical equipment to perform an inspection. The state of the earth changes day by day due to wind and rain or due to a deterioration over time, and the ground resistance value deviates from a predetermined range and a repair is required. According to the present embodiment, it is possible to visualize the change by utilizing the fact that a leakage voltage from the electrical equipment or the like appears as an electric field intensity according to an increase in ground resistance value. Since a place where a deterioration progresses at a certain change rate or more can be spatially grasped, the present embodiment is advantageous in that condition based maintenance (CBM) that optimizes a timing of repair or inspection for each area can be realized.

### Fourth Embodiment

In a fourth embodiment, the state determination unit 200 includes a baseline calculation unit 400 that calculates a baseline of electromagnetic field data acquired in the past, and the state determination unit 200 determines a state based on a discrepancy degree between the electromagnetic field information received by the electromagnetic field data input unit 102 and the baseline.

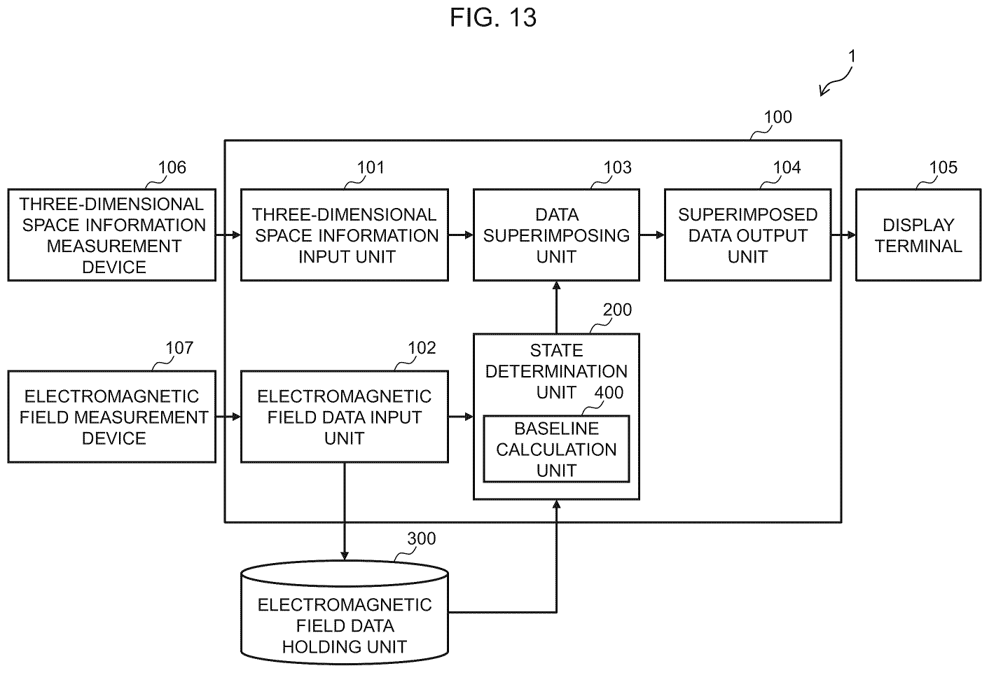

FIG. 13 is a block diagram illustrating an overall configuration of a monitoring system 1 according to the fourth embodiment.

The monitoring system 1 illustrated in FIG. 13 is different from the monitoring system 1 illustrated in FIG. 9 in that the state determination unit 200 includes a baseline calculation unit 400, and the other points are the same.

The baseline calculation unit 400 is normally provided in the state determination unit 200, receives electromagnetic field data from the electromagnetic field data holding unit 300, and calculates a baseline based on past data. The baseline means a normal value of electromagnetic field information included in electromagnetic field data in a certain area, and is, for example, an electromagnetic field intensity that constantly exists in the place due to environmental noise.

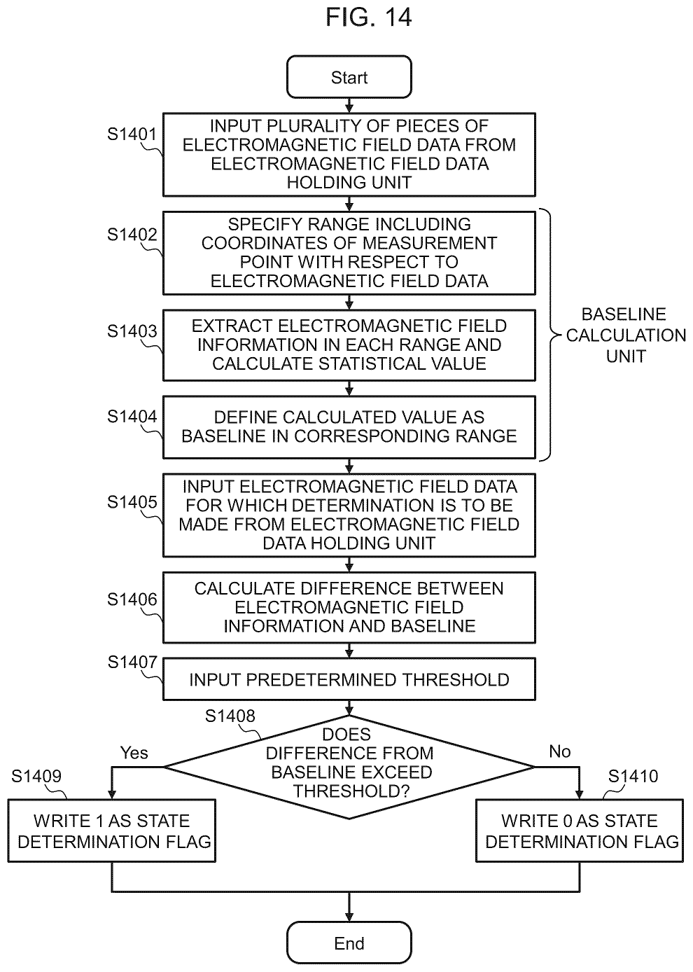

FIG. 14 is a flowchart illustrating a method for determining a state of the electrical equipment by the state determination unit 200 in the fourth embodiment.

First, the electrical equipment state monitoring system 100 inputs a plurality of pieces of electromagnetic field data from the electromagnetic field data holding unit 300 to the baseline calculation unit 400 (S1401).

Next, the baseline calculation unit 400 specifies a range including coordinates of a measurement point with respect to the input electromagnetic field data (S1402). Then, a range ID is assigned to each range.

Next, the baseline calculation unit 400 extracts electromagnetic field information in each range and calculates a statistical value (S1403).

Furthermore, the baseline calculation unit 400 defines the calculated value as a baseline in the corresponding range (S1404).

Then, the electrical equipment state monitoring system 100 inputs electromagnetic field data for which a determination is to be made from the electromagnetic field data holding unit 300 to the state determination unit 200 (S1405).

Further, the state determination unit 200 calculates a difference and a change rate between the electromagnetic field information included in the electromagnetic field data input in S1405 and the baseline (S1406).

Next, the state determination unit 200 reads a predetermined threshold (S1407).

Then, the state determination unit 200 determines whether the difference or the change rate from the baseline is equal to or larger than the threshold (S1408).

As a result, when the calculated difference or change rate exceeds the threshold (Yes in S1408), the state determination unit 200 writes 1 as a state determination flag (S1409).

On the other hand, when the calculated difference or change rate is equal to or smaller than the threshold (No in S1408), the state determination unit 200 writes 0 as a state determination flag (S1410).

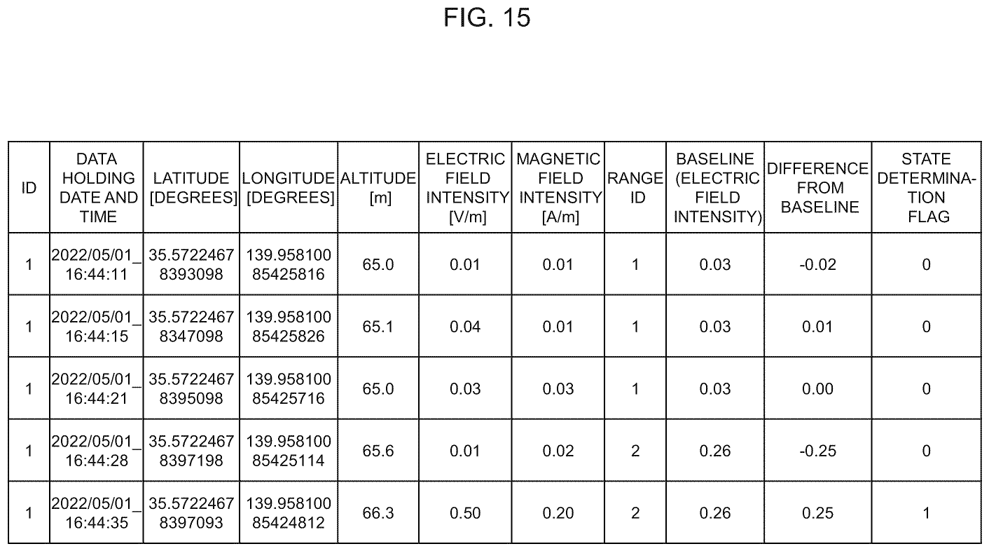

FIG. 15 is a diagram illustrating electromagnetic field data after a state determination flag is written in the fourth embodiment.

The illustrated electromagnetic field data is obtained by adding a range ID, a baseline, a difference from the baseline, and a state determination flag to the electromagnetic field data illustrated in FIG. 10. That is, the electromagnetic field data of FIG. 15 is a result of writing the range ID assigned in S1402, the baseline defined in S1404, the difference between the electromagnetic field information and the baseline calculated in S1406, and 1 or 0 as the state determination flag in S1409 or S1410 in the electromagnetic field data illustrated in FIG. 10.

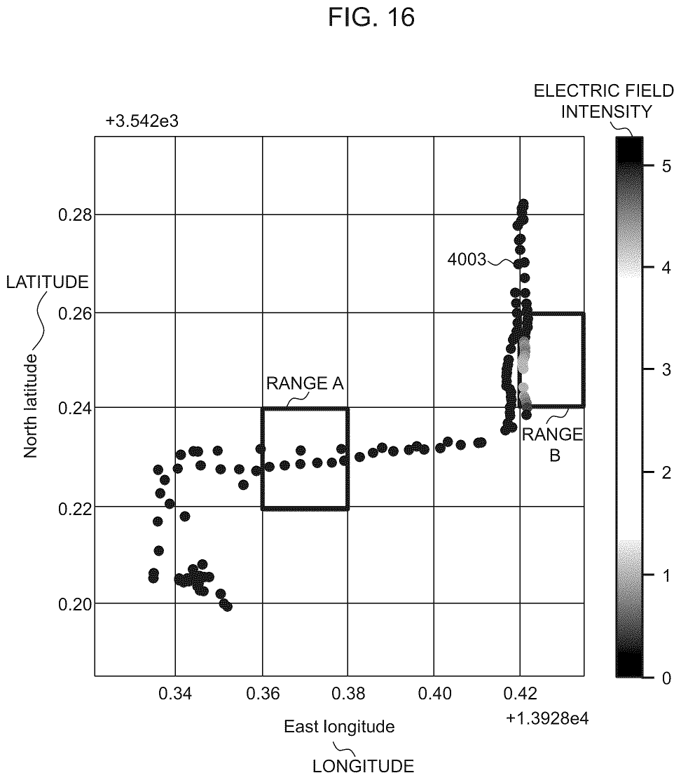

FIG. 16 is a diagram illustrating a method for defining the baseline in S1404 of FIG. 14.

In FIG. 16, the horizontal axis represents a longitude in each range, and the vertical axis represents a latitude in each range. FIG. 16 is a diagram in which an electric field intensity is plotted on a latitude and longitude space as an example of electromagnetic field information.

Since the baseline is a normal value of electromagnetic field information in a certain area, the certain area is defined. In FIG. 16, rectangular ranges divided based on longitude and latitude are defined in advance. Note that these ranges are not limited to the rectangular shape, and may be of any shape. Furthermore, any space may be defined three-dimensionally in a spherical or voxel form.

For example, a baseline in a range A can be calculated as an average value of a plurality of electric field intensities existing in the range A. Here, instead of the average value, any statistical value or representative value can be used. When baselines are calculated in the range A and the range B in FIG. 16, the electric field intensity indicated by the data in the range A is approximately 0 V/m, whereas the electric field intensity of about 3 V/m is calculated as the baseline in the range B. If the electrical equipment is in a normal state at the date and time when the electromagnetic field information is measured, the baseline indicates an electric field intensity emitted from the electrical equipment in the normal state.

The present embodiment is advantageous in that, since the state can be determined in consideration of the electromagnetic field radiation emitted at the normal time and derived from the normal operation, the detection rate is improved.

### Fifth Embodiment

In a fifth embodiment, the three-dimensional space information input unit 101 determines whether to output three-dimensional space information to the data superimposing unit 103 according to the state of the electrical equipment.

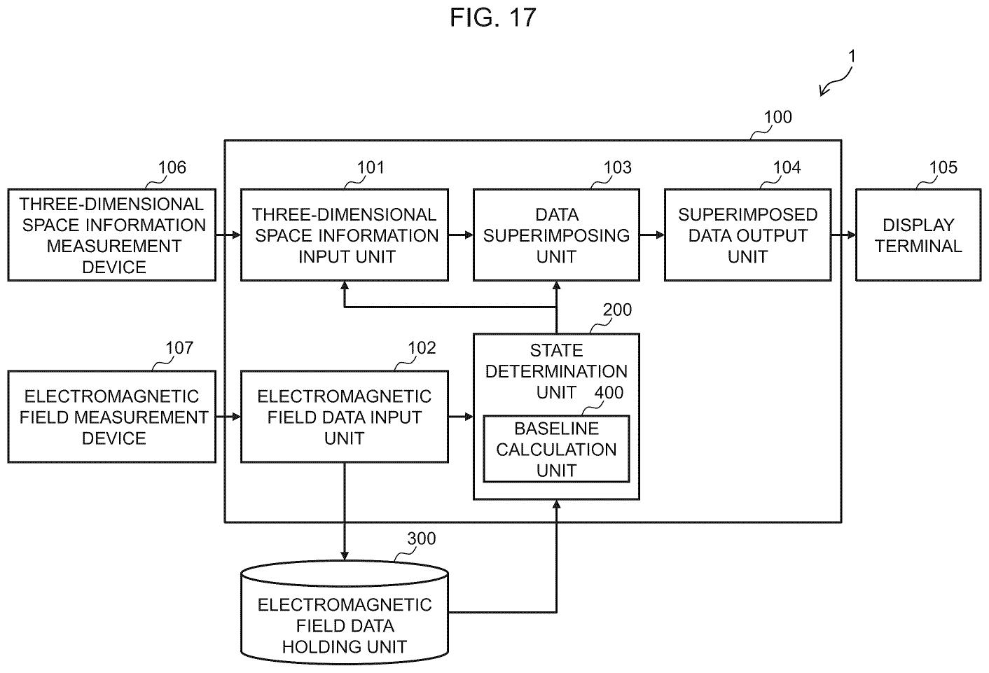

FIG. 17 is a block diagram illustrating an overall configuration of a monitoring system 1 according to the fifth embodiment.

The monitoring system 1 illustrated in FIG. 17 is different from the monitoring system 1 illustrated in FIG. 13 in that the difference or the change rate (discrepancy degree) between the electromagnetic field information and the baseline input in S1405 of FIG. 14 is input to the three-dimensional space information input unit 101, and the other points are the same.

The three-dimensional space information input unit 101 receives an input of three-dimensional space information narrowed down to an area where the difference or the change rate (discrepancy degree) is larger than the predetermined threshold, or selects and extracts the input three-dimensional space information, and outputs the three-dimensional space information to the data superimposing unit 103.

Accordingly, the number of calculation targets after the data superimposing unit 103 can be significantly reduced, which is advantageous in that the performance of the storage device such as the memory of the calculator or the processor such as the CPU is suppressed and the system maintenance cost is reduced. In addition, there is an advantage in that a calculation time is shortened by the system operation with the same specification and a waiting time at the site is minimized by immediately returning the result.

### Sixth Embodiment

In a sixth embodiment, the state determination unit 200 calculates a distance between the electrical equipment and the measurement point, and determines a state of the electrical equipment further based on information on the distance.

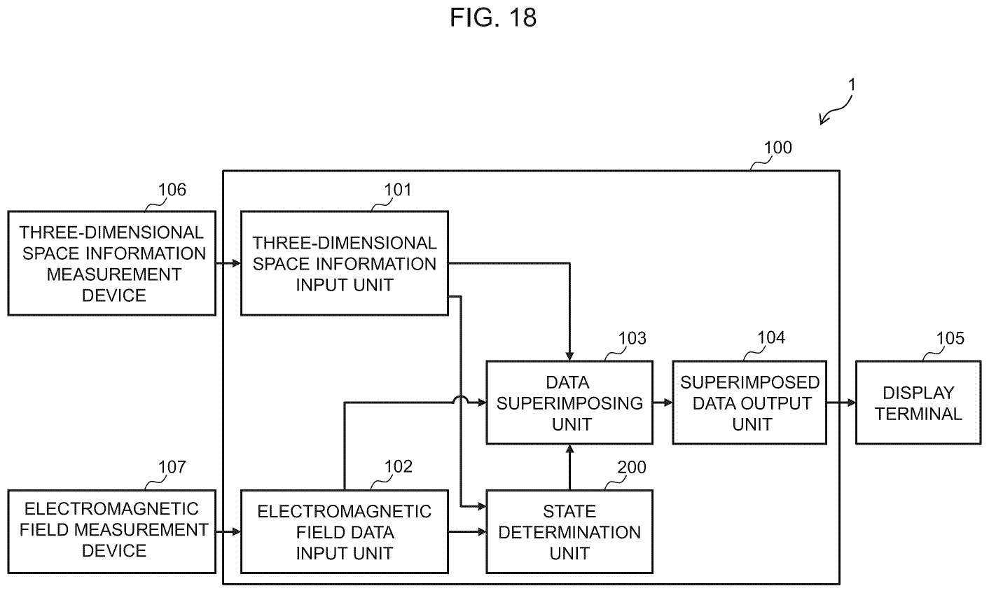

FIG. 18 is a block diagram illustrating an overall configuration of a monitoring system 1 according to the sixth embodiment.

In the monitoring system 1 illustrated in FIG. 18 as compared with the monitoring system 1 illustrated in FIG. 5, three-dimensional space information output from the three-dimensional space information input unit 101 is input to the state determination unit 200.

The state determination unit 200 calculates a distance between the electrical equipment and the measurement point based on the three-dimensional space information and the three-dimensional coordinates of the measurement point.

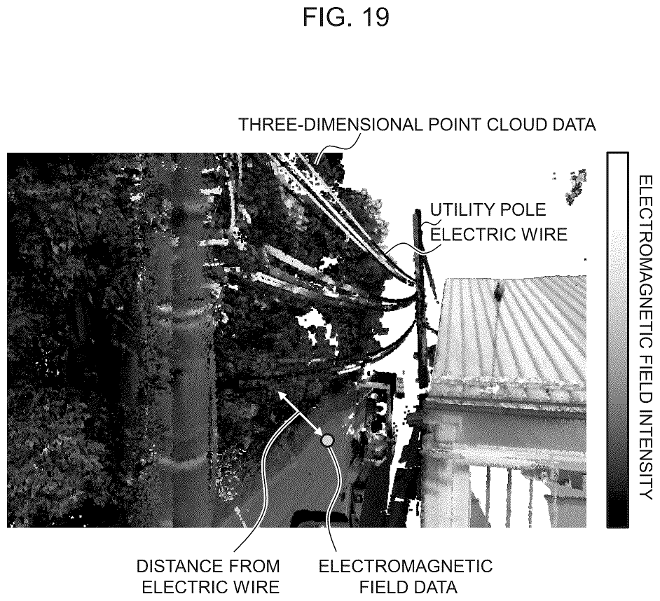

In particular, in a case where a label indicating electrical equipment exists in three-dimensional point cloud data that is three-dimensional space information as illustrated in FIG. 19, a distance between the electrical equipment and the measurement point can be calculated. Then, the state determination unit 200 determines a state of the electrical equipment further based on information on the distance. Specifically, the state determination unit 200 calculates a threshold according to the distance to be used as a threshold at the time of determining a state of the electrical equipment. In the case of FIG. 19, the state determination unit 200 calculates a distance between an electric wire, which is electrical equipment, and the measurement point, to determine a state of the electric wire.

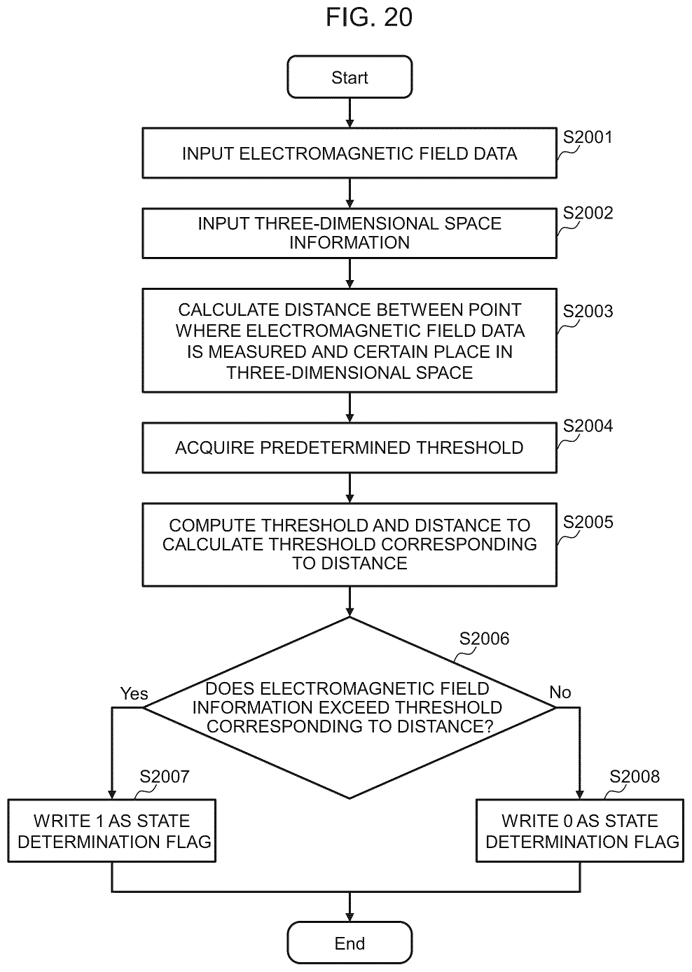

FIG. 20 is a flowchart illustrating a method for determining a state of the electrical equipment further based on information on the distance by the state determination unit 200 in the sixth embodiment.

First, the electrical equipment state monitoring system 100 inputs electromagnetic field data to the state determination unit 200 (S2001).

Next, the electrical equipment state monitoring system 100 inputs three-dimensional space information to the state determination unit 200 (S2002).

Next, the state determination unit 200 calculates a distance between a point where the electromagnetic field data is measured and a certain place in the three-dimensional space (S2003).

Further, the state determination unit 200 acquires a predetermined threshold (S2004).

Furthermore, the state determination unit 200 computes a threshold and a distance to calculate the threshold corresponding to the distance (S2005).

Then, the state determination unit 200 determines whether the electromagnetic field information included in the electromagnetic field data exceeds the threshold corresponding to the distance (S2006).

As a result, when the electromagnetic field information included in the electromagnetic field data exceeds the threshold (Yes in S2006), the state determination unit 200 writes 1 as a state determination flag (S2007).

On the other hand, when the electromagnetic field information included in the electromagnetic field data is equal to or smaller than the threshold (No in 2006), the state determination unit 200 writes 0 as a state determination flag (S2008).

In general, the electric field intensity and the magnetic field intensity may be attenuated as the electrical equipment is far away from the radiation source. Therefore, the use of the threshold based on the distance is advantageous in that the accuracy in determining the state of the electrical equipment is improved. In addition, the outputting of the calculated distance in the directly superimposed manner is advantageous in that it is possible to guarantee that the observer or the measurement device acquires the data of the monitoring target at an appropriate distance or to evaluate its safety.

### Seventh Embodiment

In a seventh embodiment, the state determination unit 200 determines a state of the electrical equipment based on at least one of a voltage, a current, and a power of the electrical equipment obtained by adding the information on the distance.

An overall configuration of a monitoring system 1 according to the seventh embodiment is similar to that of the sixth embodiment illustrated in FIG. 18.

By using the distance for which the calculation method is described in the sixth embodiment, the voltage and current of the monitoring target can be estimated from the electric field data and the magnetic field data.

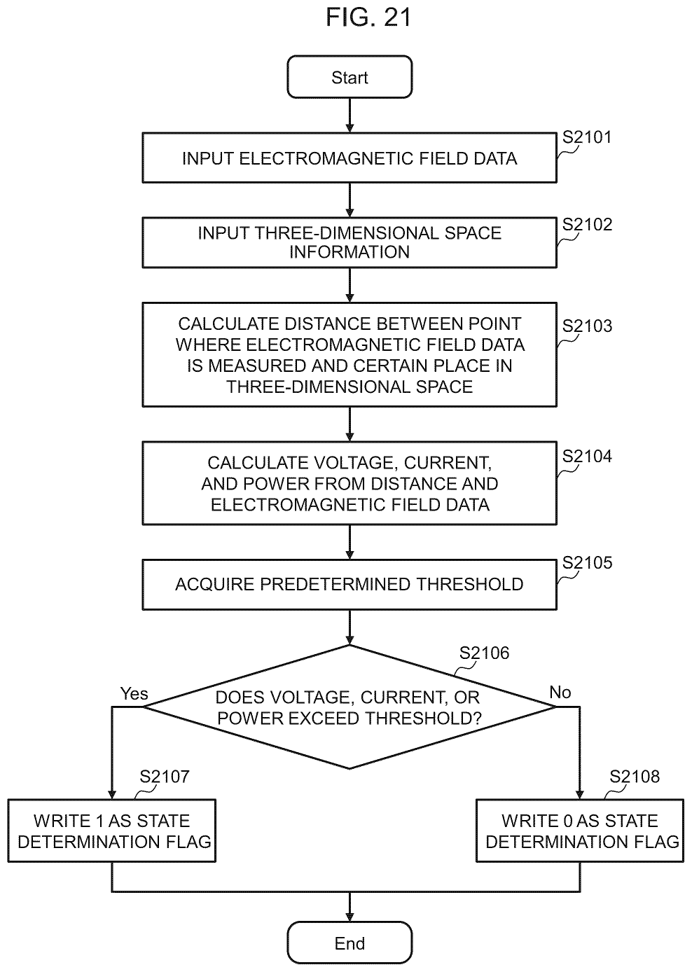

FIG. 21 is a flowchart illustrating a method for determining a state of the electrical equipment further based on information on the distance by the state determination unit 200 in the seventh embodiment.

In FIG. 21, S2101 to S2103 are the same as S2001 to S2003 of FIG. 20.

After S2103, the state determination unit 200 calculates at least one of a voltage, a current, and a power from the distance and the electromagnetic field data (S2104).

Next, the state determination unit 200 acquires a predetermined threshold (S2105).

Then, the state determination unit 200 determines whether any of the calculated voltage, current, and power exceeds the threshold (S2106).

As a result, when any of the calculated voltage, current, and power exceeds the threshold (Yes in S2106), the state determination unit 200 writes 1 as a state determination flag (S2107).

On the other hand, when any of the calculated voltage, current, and power is equal to or smaller than the threshold (No in 2106), the state determination unit 200 writes 0 as a state determination flag (S2108).

A specific example of the calculation will be described below.

For example, for an electric field intensity radiated from a single-phase overhead distribution line, it is known concerning an attenuation characteristic in a direction perpendicular to a line that a distance characteristic of an electric field to a side surface is proportional to a reciprocal of a square of a distance between a trunk and a measurement position.

In addition, it is assumed that a current I [A] flows through a certain electric wire. An intensity ΔH[A/m] of a magnetic field at a certain point P around the electric wire can be expressed by the following Formula 1 using a minute length Δl[m] around a point O on the electric wire and a distance r[m] from the point O to the point P according to Biot-Savart's law.

[Mathematical formula 1]

$$\begin{matrix}( Formula 1 ) & \\ Δ H = \frac{I Δ l}{4 π {r}^{2}} sin θ & ( 1 )\end{matrix}$$

Here, θ is an angle formed by a tangent of Δl and a line segment between the point O on the electric wire and the certain point P. In addition, a power can be calculated by a product of a voltage and a current.

In addition, for a complex space that is difficult to formulate, distance information or three-dimensional space information calculated by a finite element method may be input to a simulator, and a state of the electrical equipment, from which a result approximate to electromagnetic field data can be obtained, may be estimated exploratively.

The calculated voltage, current, and power are compared with predetermined thresholds as absolute values to determine a state. At this time, since the threshold can be designated as an absolute value related to the electrical equipment, a specific numerical value may be used from a predefined inspection item or the like. In addition, the state may be classified as a plurality of states by a plurality of thresholds.

According to the present embodiment, the state determination unit 200 can determine a state based on the current flowing through the electrical equipment, the voltage applied to the electrical equipment, and the power consumed by the electrical equipment, which is advantageous in that a clear index such as a rated voltage, a rated current, or a rated power determined for the electrical equipment can be used as the threshold. In addition, the classification of the cause of the abnormality of the electrical equipment into the current, the voltage, or the power is advantageous in that repair efficiency is improved. For example, in a three-phase AC distribution line, when a ground fault occurs, a zero-phase current indicating a total value of currents flowing through three phases indicates a value equal to or more than a certain value. By estimating a zero-phase current from electromagnetic field data measured at a plurality of points, it can be determined whether a ground fault has occurred.

### Eighth Embodiment

In an eighth embodiment, the electromagnetic field data includes vector information that is information on a direction to the electrical equipment, the state determination unit 200 specifies a generation source of an electromagnetic field based on the vector information, and the data superimposing unit 103 superimposes the three-dimensional space information and the electromagnetic field data based on the specified generation source.

The electromagnetic field data in the eighth embodiment includes vector information. That is, the direction can be grasped in addition to the intensity of the electromagnetic field at the measurement point. In a simple example, in a case where two pieces of electrical equipment of the same type are installed with an electromagnetic field therebetween, the state determination unit 200 can determine which piece of electrical equipment the electromagnetic field is radiated from based on the directivity of the electromagnetic field data measured around the electromagnetic field. More specifically, an electric field is usually radiated toward the ground far from the electrical equipment with a potential being generated on a surface thereof. Therefore, when a measurement point is sufficiently close to the electrical equipment, the source of the electric field exists in a direction opposite to the measured direction of the electromagnetic field. Therefore, a surface of the electric field generation source is specified based on an intersection between a straight line drawn in the direction opposite to the direction of the electromagnetic field and a surface of the electrical equipment existing in the three-dimensional space information. The surface of the generation source is partially or entirely output to the data superimposing unit 103, and data is combined, for example, with the color being changed.

According to the present embodiment, the generation source of electromagnetic field data determined to be in a certain state can be specified, making it possible to more quickly find an object when an abnormality such as an accident or a failure occurs.

### Ninth Embodiment

In a ninth embodiment, the electrical equipment state monitoring system 100 includes a difference calculation unit 700 that calculates a difference between a plurality of pieces of three-dimensional space information, and the three-dimensional space information input unit 101 outputs the three-dimensional space information to the data superimposing unit 103 when the difference is larger than a predetermined threshold.

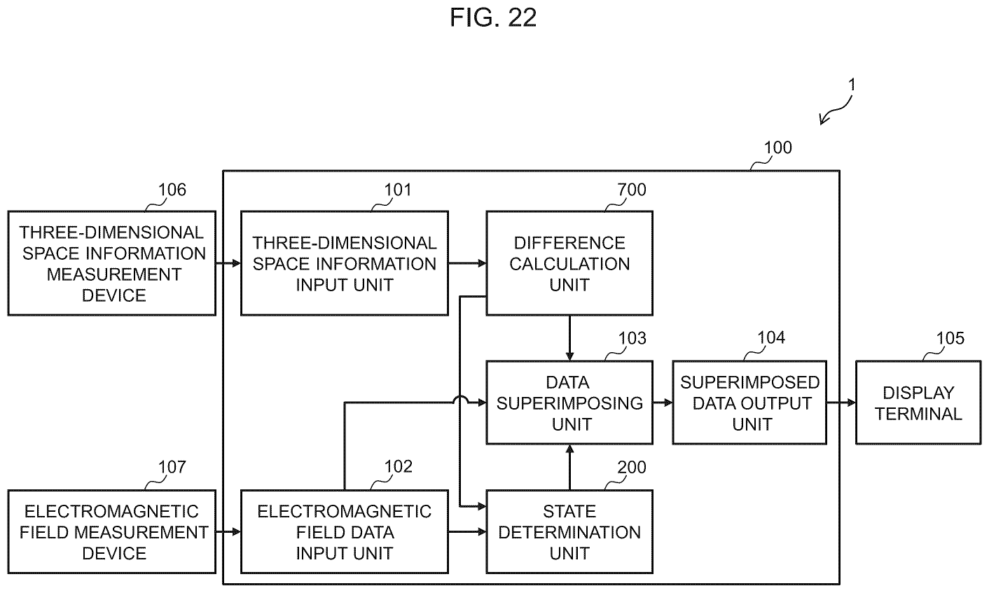

FIG. 22 is a block diagram illustrating an overall configuration of a monitoring system 1 according to the ninth embodiment.

The monitoring system 1 illustrated in FIG. 22 is different from the monitoring system 1 illustrated in FIG. 18 in that the difference calculation unit 700 is added to the electrical equipment state monitoring system 100, and the other points are the same.

When a plurality of pieces of three-dimensional space information are input to the three-dimensional space information input unit 101, the difference calculation unit 700 calculates a difference between at least two pieces of the three-dimensional space information. The difference is calculated for each three-dimensional coordinate, and three-dimensional coordinates on which the difference is equal to or larger than a predetermined value are extracted. The extracted three-dimensional coordinates are used as keys to refer to the three-dimensional space information, and the three-dimensional space information is partially or entirely output to the state determination unit 200.

In general, the life expectancy of the electrical equipment is long, lasting several years, and the surroundings thereof may not change much. In addition, since power distribution equipment and the like are laid installed throughout the city and prefecture, the monitoring area is wide. The present embodiment is advantageous in that the monitoring cost can be reduced by detecting that the electrical equipment or the surroundings thereof have changed by a certain amount or more and performing remote monitoring only in the area.

### Tenth Embodiment

A tenth embodiment is characterized by the configuration of the electromagnetic field measurement device 107.

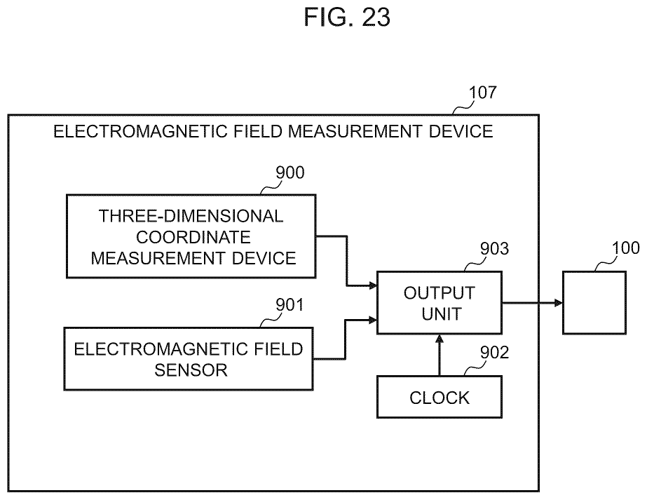

FIG. 23 is a block diagram illustrating a configuration of the electromagnetic field measurement device 107 according to the tenth embodiment.

The electromagnetic field measurement device 107 illustrated in FIG. 23 includes a three-dimensional coordinate measurement device 900, an electromagnetic field sensor 901, a clock 902, and an output unit 903.

The three-dimensional coordinate measurement device 900 is a device that measures three-dimensional coordinates of a predetermined area based on a predetermined method. As a method of measuring three-dimensional coordinates, a satellite positioning system such as a global positioning system (GPS) can be used, or a relative distance from a predetermined reference point can be measured by a sound wave, a beam, or a distance measurement device including various encoders. Alternatively, a horizontal position and a vertical position, that is, a latitude and longitude and an altitude, may be separately measured by different methods.

The electromagnetic field sensor 901 is a device that measures at least one of an electric field and a magnetic field as electromagnetic field information at a measurement point based on a predetermined method. As a method of measuring an electric field, a voltage generated across a parallel plate electrode in proportion to a spatial electric field intensity can be converted into digital data by an analog-digital conversion circuit, or a transducer such as an optical electric field element can be used. As a method of measuring a magnetic field, a coil, a magnetoresistive sensor element, or a Hall element can be used.

The three-dimensional coordinate measurement device 900 and the electromagnetic field sensor 901 are connected to the output unit 903, and the output unit 903 outputs the three-dimensional coordinates and the electromagnetic field information with a time measured by the clock 902.

In this case, the clock 902 functions as a clocking unit for performing time synchronization of the data output from the electromagnetic field sensor with the measurement of the three-dimensional coordinates.

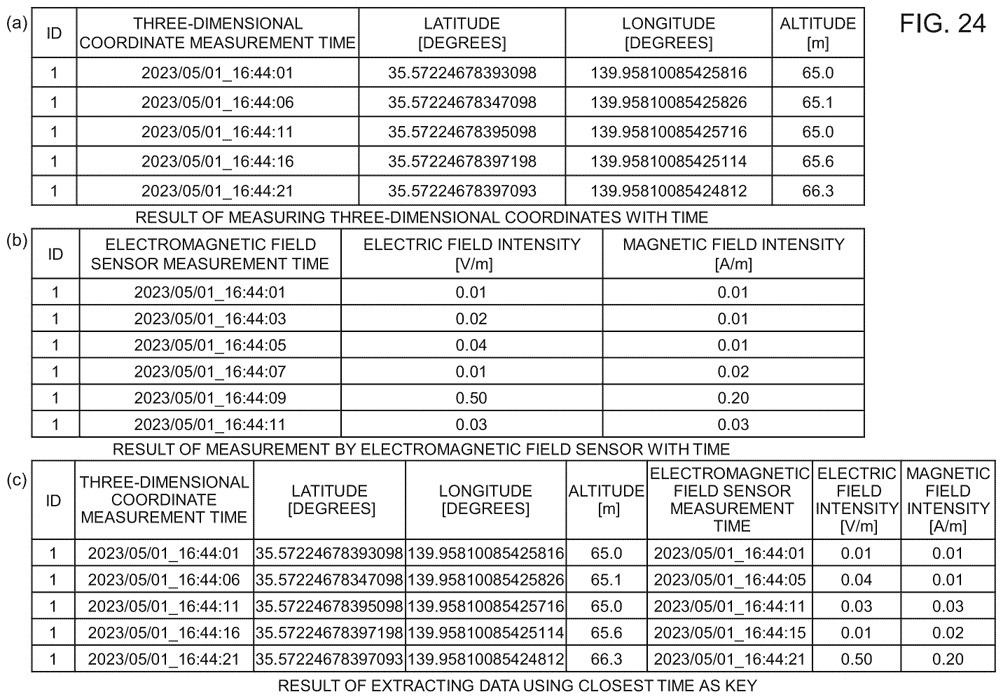

FIGS. 24A and 24B are diagrams illustrating examples of data output by the output unit 903 in the tenth embodiment.

Among them, FIG. 24A is a result of measuring three-dimensional coordinates to which a time is assigned. In this manner, the clock 902 assigns a measurement time to data measured by the three-dimensional coordinate measurement device 900.

FIG. 24B is a result of measurement by the electromagnetic field sensor 901 to which a time is assigned. In this manner, the clock 902 assigns a measurement time to data measured by the electromagnetic field sensor 901.

According to the present embodiment, in a case where the three-dimensional coordinate measurement device 900 and the electromagnetic field sensor 901 have a certain distance relationship, even if the measurement timings of the three-dimensional coordinate measurement device 900 and the electromagnetic field sensor 901 are different from each other, data to which the closest times are assigned by the clock 902 are extracted. Then, for example, by forming data as illustrated in FIG. 24C, the most appropriate data can be referred to as three-dimensional coordinates at which a measurement is performed by the electromagnetic field sensor 901. As a result, it is possible to reduce the effort required to match the measurement timings of the three-dimensional coordinate measurement device 900 and the electromagnetic field sensor 901

### Eleventh Embodiment

An eleventh embodiment is also characterized by the configuration of the electromagnetic field measurement device 107.

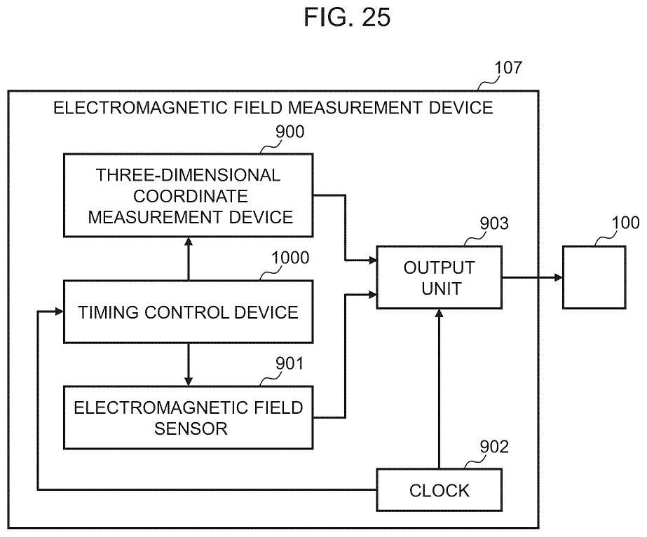

FIG. 25 is a block diagram illustrating a configuration of the electromagnetic field measurement device 107 according to the eleventh embodiment.

The electromagnetic field measurement device 107 illustrated in FIG. 25 is different from the electromagnetic field measurement device 107 illustrated in FIG. 23 in that a timing control device 1000 is added, and the other points are the same.

The time output from the clock 902 is input to the timing control device 1000, and the three-dimensional coordinate measurement device 900 and the electromagnetic field sensor 901 are driven at a predetermined time. It can also be said that the timing control device 1000 controls the measurement timing of the three-dimensional coordinate measurement device 900 and the electromagnetic field sensor 901 based on the time measured by the clock 902. The timing control device 1000 can drive the three-dimensional coordinate measurement device 900 and the electromagnetic field sensor 901 at regular time intervals.

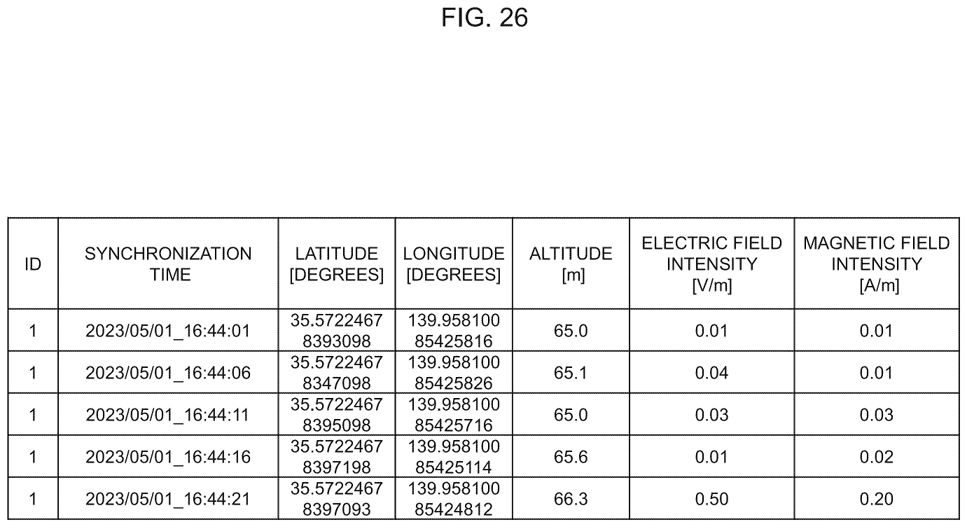

FIG. 26 is a diagram illustrating an example of data output by the output unit 903 in the eleventh embodiment.

As illustrated in FIG. 26, the measurement results of the three-dimensional coordinate measurement device 900 and the electromagnetic field sensor 901 are recorded and output at a time synchronized by the timing control device 1000.

The present embodiment is advantageous in that electromagnetic field information can be periodically updated for a monitoring area and a change in state of the electrical equipment can be periodically monitored.

In addition, by driving the three-dimensional coordinate measurement device 900 and the electromagnetic field sensor 901 at the same timing, it is possible to more accurately record a measurement point at which a measurement is performed by the electromagnetic field sensor.

### Twelfth Embodiment

In a twelfth embodiment, the three-dimensional space information measurement device 106 and the electromagnetic field measurement device 107 are mounted on the same moving object.

The moving object is an object that moves in a three-dimensional space, and includes a living object such as a human, a taxiing object such as a vehicle or a cart, a flying object such as a drone or an airplane, an inspection robot that moves in a tunnel or in the ground, and the like.

The present embodiment is advantageous in that, since electromagnetic field data and three-dimensional space information can be acquired while moving in the three-dimensional space, monitoring for a wider area and monitoring using information from a plurality of angles can be realized.

In addition, the present embodiment is advantageous in that, by mounting the devices on a moving object that can move autonomously, the cost can be reduced as compared with that when a measurement is performed manually, and a high place, a difficult place, a dangerous place, or the like, which is difficult to measure manually, can be remotely monitored.

### Thirteenth Embodiment

In a thirteenth embodiment, the display terminal 105 is carried by a worker who measures electromagnetic field data, and the display terminal 105 displays an instruction regarding measurement by an operator who has viewed superimposed data. At this time, the monitoring system 1 includes a visualization unit 802 that inputs superimposed data and visualizes at least a part of a monitoring target area in a virtual three-dimensional space by three-dimensional space information and electromagnetic field data.

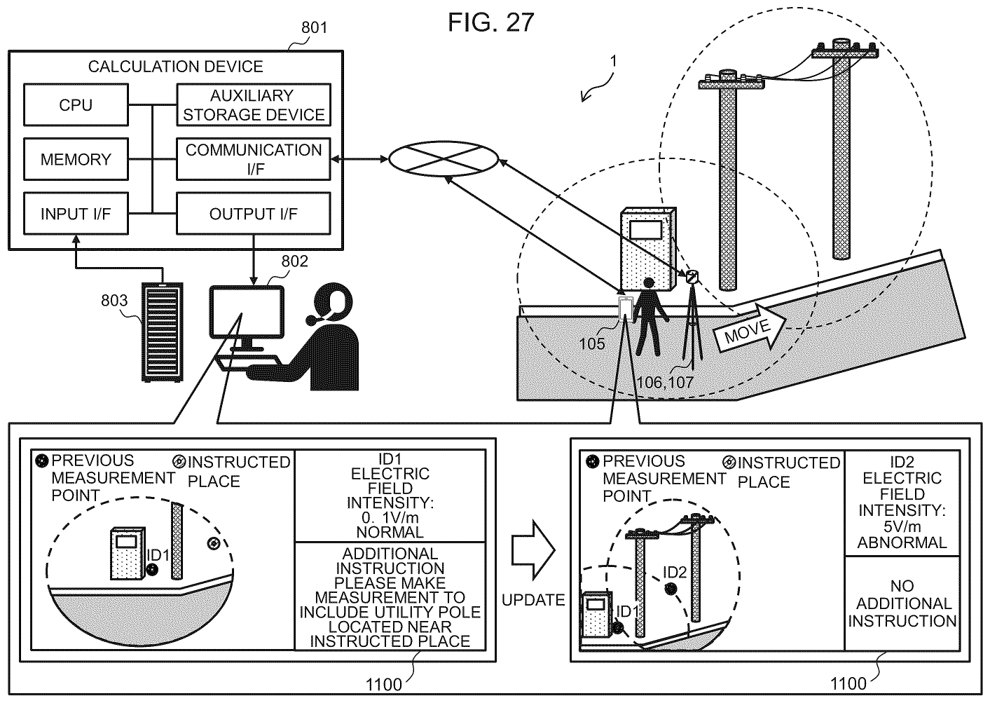

FIG. 27 is a diagram illustrating a method for measuring a state of electrical equipment in the thirteenth embodiment.

A worker who acquires electromagnetic field data and three-dimensional space information for a predetermined space in which electrical equipment is disposed acquires data for a predetermined area using the three-dimensional space information measurement device 106 and the electromagnetic field measurement device 107, and inputs the data to a calculation device 801. The data may be input wirelessly via public radio.

The calculation device 801 is a form of the electrical equipment state monitoring system 100, superimposes the input data, and displays the superimposed data on a visualization unit 802 of a monitoring device 803 that is located in hand of an operator who is located at a remote place. The monitoring device 803 includes an input instruction unit 1100 that inputs and instructs at least one of a data measurement place and a measurement data type, and is operated by an input via a keyboard or a mouse connected to an input interface (I/F) of the calculation device 801, a voice, or the like.

The instruction input to the input instruction unit 1100 can be displayed in a superimposed manner on the virtual three-dimensional space, which is advantageous in that the intuitive understanding of the instruction is promoted.

The instruction input to the input instruction unit 1100 can also be viewed from the display terminal 105 at the hand of the worker, so that the worker moves or performs an additional measurement based on the instruction.

Data obtained by the additional measurement is input back to the calculation device 801, thereby updating the data output to the monitoring device 803, and updating the display of the visualization unit 802 as well.

The present embodiment is advantageous in that an operator who is located at a remote place can acquire and interpret electrical equipment information at the remote place based on an intuitive instruction. In addition, the worker only needs to have knowledge to handle the measurement device, and can perform work even though the work has no knowledge about the electrical equipment, which is advantageous in that the cost for securing the worker is reduced.

Furthermore, a method for remotely monitoring a condition of electrical equipment in an intuitive manner will be described. In this method, the electrical equipment state monitoring system 100 receives three-dimensional space information acquired in an area including a part of a target to be remotely monitored and electromagnetic field data derived from the state of the electrical equipment. Either wireless communication or wired communication may be used for the reception. The electrical equipment state monitoring system 100 generates superimposed data in which the electromagnetic field data is superimposed on the three-dimensional space information based on three-dimensional coordinates, and transmits the generated superimposed data to the monitoring device 803 including the visualization unit 802. Either wireless communication or wired communication may be used for the transmission. The electrical equipment state monitoring system 100 displays the superimposed data as a virtual three-dimensional space via the monitoring device 803. The monitoring device 803 can visualize the superimposed data as VR by displaying the superimposed data as 360-degree content in a head mounted display, or can visualize the superimposed data as AR by transmitting the superimposed data together with a two-dimensional image captured by a camera to a display device to which the camera is attached and displaying the superimposed data in an overlaid state.

The present embodiment is advantageous in that a state of electrical equipment existing in a monitoring target area can be intuitively monitored even remotely using electromagnetic field data displayed in a virtual three-dimensional space.

The processing performed by the electrical equipment state monitoring system 100 in the present embodiment described above is realized by cooperation of software and hardware resources. That is, a processor such as a CPU installed in the electrical equipment state monitoring system 100 loads a program for realizing each function of the electrical equipment state monitoring system 100 onto a main memory and executes the program to realize each function.

Therefore, the processing performed by the electrical equipment state monitoring system 100 described above can be regarded as an electrical equipment state monitoring method for monitoring a state of electrical equipment by a processor executing a program recorded in a memory, the electrical equipment state monitoring method including: receiving inputs of three-dimensional space information about an area including the electrical equipment and electromagnetic field data including electromagnetic field information regarding an intensity of an electromagnetic field derived from the electrical equipment and three-dimensional coordinates of a point where the electromagnetic field information is acquired; superimposing the three-dimensional space information and the electromagnetic field data in the same space based on the three-dimensional coordinates to generate superimposed data; and outputting the superimposed data.

Note that the program for realizing the present embodiment can be provided not only by a communication means but also through a recording medium such as a CD-ROM where the program is stored.

Although the present embodiment has been described above, the technical scope of the present invention is not limited to the scope of the above-described embodiment. It is apparent from the appended claims that various modifications or improvements made to the above-described embodiment fall within the technical scope of the present invention.

1. An electrical equipment state monitoring system for monitoring a state of electrical equipment, the electrical equipment state monitoring system comprising:
a reception unit that receives inputs of three-dimensional space information about an area including the electrical equipment and electromagnetic field data including electromagnetic field information regarding an intensity of an electromagnetic field derived from the electrical equipment and three-dimensional coordinates of a point where the electromagnetic field information is acquired;
a data superimposing unit that superimposes the three-dimensional space information and the electromagnetic field data in the same space based on the three-dimensional coordinates to generate superimposed data; and
a superimposed data output unit that outputs the superimposed data from the electrical equipment state monitoring system.

2. The electrical equipment state monitoring system according to claim 1, further comprising a state determination unit that determines a state of the electrical equipment based on the electromagnetic field data,
wherein the data superimposing unit further superimposes information on the state of the electrical equipment.

3. The electrical equipment state monitoring system according to claim 2, wherein the state determination unit determines the state of the electrical equipment based on the electromagnetic field data received by the reception unit and electromagnetic field data acquired in the past.

4. The electrical equipment state monitoring system according to claim 3, wherein the state determination unit includes a baseline calculation unit that calculates a baseline of electromagnetic field information acquired in the past, and
the state determination unit determines the state based on a discrepancy degree between the electromagnetic field information received by the reception unit and the baseline.

5. The electrical equipment state monitoring system according to claim 4, wherein when the discrepancy degree is larger than a predetermined threshold, the reception unit outputs the three-dimensional space information to the data superimposing unit.

6. The electrical equipment state monitoring system according to claim 2, wherein the state determination unit calculates a distance between the electrical equipment and the point based on the three-dimensional space information and the three-dimensional coordinates, and determines the state of the electrical equipment further based on information on the distance.

7. The electrical equipment state monitoring system according to claim 6, wherein the state determination unit determines the state of the electrical equipment based on at least one of a voltage, a current, and a power of the electrical equipment obtained by adding the information on the distance.

8. The electrical equipment state monitoring system according to claim 2, wherein the electromagnetic field data includes vector information that is information on a direction to the electrical equipment,
the state determination unit specifies a generation source of the electromagnetic field based on the vector information, and
the data superimposing unit superimposes the three-dimensional space information and the electromagnetic field data based on the specified generation source.

9. The electrical equipment state monitoring system according to claim 1, further comprising a difference calculation unit that calculates a difference between a plurality of pieces of three-dimensional space information,
wherein when the difference is larger than a predetermined threshold, the reception unit outputs the three-dimensional space information to the data superimposing unit.

10. A monitoring system comprising:
a reception unit that receives inputs of three-dimensional space information about an area including the electrical equipment and electromagnetic field data including electromagnetic field information regarding an intensity of an electromagnetic field derived from the electrical equipment and three-dimensional coordinates of a point where the electromagnetic field information is acquired;
a data superimposing unit that superimposes the three-dimensional space information and the electromagnetic field data in the same space based on the three-dimensional coordinates to generate superimposed data; and
a superimposed data output unit that outputs the superimposed data from the electrical equipment state monitoring system;
a three-dimensional space information measurement device that measures the three-dimensional space information;
an electromagnetic field measurement device that measures the electromagnetic field information in association with the three-dimensional coordinates of the point; and
a display device that displays data superimposed by the electrical equipment state monitoring system,
wherein the electromagnetic field measurement device includes
a three-dimensional coordinate measurement device that measures the three-dimensional coordinates,
an electromagnetic field sensor that measures at least one of an electric field and a magnetic field as the electromagnetic field information, and
a clocking unit that performs time synchronization of data output from the electromagnetic field sensor with the measurement of the three-dimensional coordinates.

11. The monitoring system according to claim 10, wherein a measurement timing of the three-dimensional coordinate measurement device and the electromagnetic field sensor is controlled based on a time measured by the clocking unit.

12. The monitoring system according to claim 10, wherein the three-dimensional space information measurement device and the electromagnetic field measurement device are mounted on the same moving object.

13. The monitoring system according to claim 10, wherein the display device is carried by a worker who measures the electromagnetic field data, and
the display device displays an instruction for measurement by an operator who has viewed the superimposed data.

14. The monitoring system according to claim 10, further comprising a visualization unit that inputs data superimposed by the electrical equipment state monitoring system and visualizes at least a part of a monitoring target area in a virtual three-dimensional space by the three-dimensional space information and the electromagnetic field data.

15. An electrical equipment state monitoring method for monitoring a state of electrical equipment by a processor executing a program recorded in a memory, the method comprising:
receiving inputs of three-dimensional space information about an area including the electrical equipment and electromagnetic field data including electromagnetic field information regarding an intensity of an electromagnetic field derived from the electrical equipment and three-dimensional coordinates of a point where the electromagnetic field information is acquired;
superimposing the three-dimensional space information and the electromagnetic field data in the same space based on the three-dimensional coordinates to generate superimposed data; and
outputting the superimposed data.
